(19) United States
(12) Patent Application Publication
(10) Pub. No.: US 2016/0209743 A1
(43) Pub. Date: Jul. 21, 2016

(54) PHOTOSENSITIVE RESIN COMPOSITION FOR FORMING MEMBER HAVING CURVED SHAPE, PHOTOSENSITIVE RESIN FILM FOR FORMING MEMBER HAVING CURVED SHAPE USING SAID COMPOSITION, AND LENS MEMBER MANUFACTRED USING SAID COMPOSITION OR SAID FILM

(71) Applicant: HITACHI CHEMICAL COMPANY, LTD., Tokyo (JP)

(72) Inventors: Masao UCHIGASAKI, Tsukuba-shi, Ibaraki (JP); Daichi Sakai, Tsukuba-shi, Ibaraki (JP); Yutaka Kawakami, Yuki-shi, Ibaraki (JP); Toshihiro KURODA, Oyama-shi, Tochigi (JP)

(73) Assignee: Hitachi Chemical Company, Ltd., Tokyo (JP)

(21) Appl. No.: 14/916,248

(22) PCT Filed: Sep. 1, 2014
(86) PCT No.: PCT/JP2014/072949

§ 371 Date: Mar. 3, 2016

(30) Foreign Application Priority Data
Sep. 4, 2013 (JP) 2013-183517

(51) Int. Cl. G03F 7/033; G03F 7/00; G02B 1/04

(52) U.S. Cl. CPC G03F 7/033; G02B 1/041; G03F 7/0005

(57) ABSTRACT

[Problem] To provide a photosensitive resin composition for forming a member having a curved shape, which is soluble in an alkaline aqueous solution, and with which a pattern can be formed comparatively freely, wherein a lens member formed by using the said composition is excellent in heat resistance, formability of a curved shape, and transparency. [Solution] The said photosensitive resin composition for forming a member having a curved shape comprises (A) a polymer, (B) a polymerizable compound having a group which thermally reacts with the said polymer, and (C) a polymerization initiator.

### TECHNICAL FIELD

The present invention relates to a photosensitive resin composition for forming a member having a curved shape, a photosensitive resin film for forming a member having a curved shape, and a lens member formed by using the said composition or the said film.

### BACKGROUND ART

In an IC technology and an LSI technology, in order to improve an operation speed as well as an integration degree, part of an electrical wiring on an electrical wiring board is replaced with an optical wiring such as an optical fiber and an optical waveguide so that an optical signal is used in place of an electrical signal.

For example, Patent Literature 1 discloses that an optical wave guide film is arranged above an IC chip provided with an optical element on surface thereof thereby carrying out optical communication between the IC chip and the optical waveguide film. However, when optical communication is made between a substrate, which is provided with an optical communication means such as an optical element, and an optical communication means such as an optical waveguide as shown in Patent Literature 1, there are problems that, unless these optical communication means are positioned with high accuracy to each other upon mounting them, the optical communication cannot be made, and that, unless a light is concentrated, optical loss (signal strength) decreases.

In order to solve these problems, a micro lens is arranged on surface of the substrate.

For example, Patent Literature 2 discloses a substrate provided with a lens, that is, a micro lens arranged on surface of a transparent substrate is disclosed. To produce this substrate provided with the lens, a photosensitive resin resist is formed on surface of the transparent substrate, and also, a light shielding film having an opening portion is formed on backside of the substrate. Then, a light is radiated from the light shielding film side to expose the photosensitive resin resist in a portion which exists at a location opposite to the opening portion of the light shielding film; and thereafter, development thereof is carried out to form a columnar resist structure. After that, this resist structure is heated to cause thermally sagged surface of the resist structure, so that the micro lens is produced.

### CITATION LIST

### Patent Literature

Patent Literature 1: Japanese Patent Laid-Open Publication No. 2006-11210
Patent Literature 2: Japanese Patent Laid-Open Publication No. 2004-361858
Patent Literature 3: Japanese Patent Laid-Open Publication No. 2006-91537

### SUMMARY OF INVENTION

### Technical Problems

As to the material for forming a lens, for example, as shown in Patent Literature 3, a resin composition comprising a non-photosensitive polymer and a compound having an ethylenic unsaturated group is disclosed, wherein the curved shape is realized by heat treatment. However, the material system like this leads to sparse crosslinking between the polymer component and other components thereby causing disturbance in the shape of the lens by the post-heating treatment such as the reflow treatment after formation of the lens; and therefore, there has been a concern of an adverse effect on the light concentration. On the other hand, a photosensitive polymer component, if it is used, leads to dense crosslinking during exposure to a light, the disturbance in the shape can be suppressed; on the other hand, however, it is expected that realization of the curved shape becomes difficult so that an intended lens curvature may not be obtained.

The present invention was made to solve the problems mentioned above, so that an object thereof is to provide a highly heat-resistant photosensitive resin composition for forming a member having a curved shape, a photosensitive resin film for forming a member having a curved shape, and a lens member formed by using the said composition or the said film.

### Solution to Problems

Inventors of the present invention carried out an extensive investigation to solve the problems mentioned above, and as a result of it, it was found that the above-mentioned problems can be solved by using a photosensitive resin composition for forming a member having a curved shape, the said composition comprising a polymer, a polymerizable compound having a group which thermally reacts with the said polymer, and a polymerization initiator. The present invention was completed on the basis of such finding.

That is, the present invention provides: a photosensitive resin composition for forming a member having a curved shape comprising (A) a polymer, (B) a polymerizable compound having a group which thermally reacts with the said polymer, and (C) a polymerization initiator; a photosensitive resin film for forming a member having a curved shape using the photosensitive resin composition for forming a member having a curved shape; and a lens member having excellent heat resistance, formability of a curved shape, and transparency, which is formed by using the photosensitive resin composition for forming a member having a curved shape or by using the photosensitive resin film for forming a member having a curved shape.

### Advantageous Effects of Invention

According to the present invention, what can be provided are: a photosensitive resin composition for forming a member having a curved shape which is soluble in an alkaline aqueous solution and with which a pattern can be formed comparatively freely; a photosensitive resin film for forming a member having a curved shape which is obtained from the said composition; and a lens member having excellent heat resistance, formability of a curved shape, and transparency, which is formed by using them.

### BRIEF DESCRIPTION OF DRAWINGS

FIG. 1 shows the cross section views illustrating the method for producing the lens member formed by using the photosensitive resin film for forming a member having a curved shape.

FIG. 2 shows pictures of the shapes of the lens members in Examples and Comparative Examples, respectively.

FIG. 3 shows pictures of the shapes of the resin surfaces after the heat resistance tests in Examples and Comparative Examples, respectively.

### DESCRIPTION OF EMBODIMENTS

The photosensitive resin composition for forming a member having a curved shape according to an embodiment of the present invention comprises (A) a polymer, (B) a polymerizable compound having a group which thermally reacts with the said polymer, and (C) a polymerization initiator, wherein the resin composition is preferably curable by heating or exposure to an active light beam.

Hereunder, each component used in the present invention will be explained.

### (A) Component:

As to the polymer of the (A) component, generally an alkaline-soluble polymer is preferable, wherein the alkaline-soluble polymer means that it is a polymer having an alkaline-soluble group (for example, carboxyl group, a sulfonic acid group, a phenolic hydroxyl group, an alcoholic hydroxyl group, and an amino group, etc.), so that it suffices if the polymer is soluble in an alkaline aqueous solution. There is no particular restriction in the polymer; but, an alkaline soluble (meth)acryl polymer is preferable. As to the alkaline-soluble group, a carboxyl group is preferable.

Meanwhile, the term “(meth)acryl” means an acryl and/or a methacryl.

As to the alkaline-soluble (meth)acryl polymer, there is no particular restriction in it, provided that it is soluble in a developing solution of an alkaline aqueous solution, wherein the solubility thereof is high enough to carry out an intended development to a satisfactory degree. Therefore, preferable example thereof includes polymers of (meth)acryl monomers such as a (meth)acrylic acid, various (meth)acrylate esters (such as an alkyl ester of (meth)acrylate and a hydroxyalkyl ester of (meth)acrylate), a (meth)acrylamide, and monomers having other polymerizable unsaturated group (such as styrene, α-methyl styrene, maleic anhydride, and an N-substituted or an N-unsubstituted maleimide monomer).

Among them, in view of transparency, heat resistance, and solubility into an alkaline aqueous solution, the one that has a maleimide skeleton using an N-substituted maleimide is preferable, while a copolymer with other (meth)acryl type is more preferable. Still more preferably to be used is an alkaline-soluble (meth)acryl polymer comprising in the main chain thereof a structure unit (A-1) and a structure unit (A-2) which are represented by the following general formulae (1) and (2), respectively, and furthermore, at least one structure unit selected from a structure unit (A-3) and a structure unit (A-4) which are represented by the following general formulae (3) and (4), respectively.

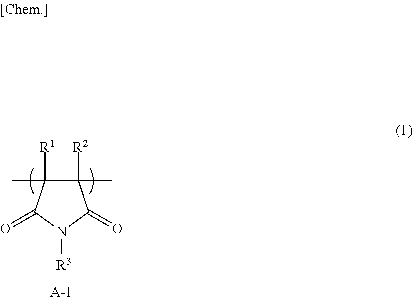

(In the formula, R¹ to R³ each independently represents any of a hydrogen atom and an organic group having 1 to 20 carbon atoms.)

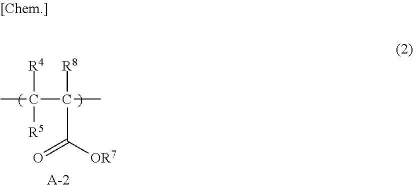

(In the formula, R⁴ to R⁶ each independently represents any of a hydrogen atom and an organic group having 1 to 20 carbon atoms, R⁷ represents any of an organic group having 1 to 20 carbon atoms.)

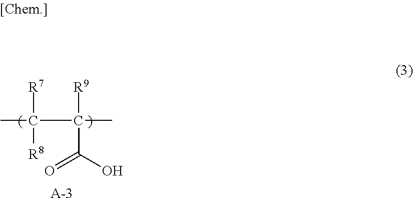

(In the formula, R⁷ to R⁹ each independently represents any of a hydrogen atom and an organic group having 1 to 20 carbon atoms.)

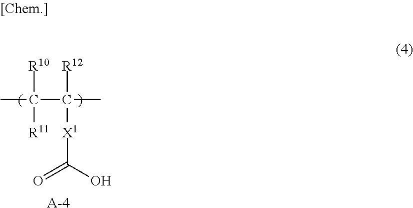

(In the formula, R¹⁰ to R¹² and X¹ each independently represents any of a hydrogen atom and an organic group having 1 to 20 carbon atoms.)

Illustrative example of the organic groups in the general formulae (1) to (4) includes monovalent or divalent groups such as an alkyl group, a cycloalkyl group, an aryl group, an aralkyl group, a carbonyl group, an alkoxy carbonyl group, an aryloxy carbonyl group, and a carbamoyl group; and these groups may be substituted further by a hydroxyl group, a halogen atom, an alkyl group, a cycloalkyl group, an aryl group, an aralkyl group, a carbonyl group, an alkoxy carbonyl group, an aryloxy carbonyl group, a carbamoyl group, an alkoxy group, an aryloxy group, an alkylthio group, an arylthio group, an amino group, a silyl group, or the like.

In the alkaline-soluble (meth)acryl polymer, content of the structure unit (A-1) derived from the maleimide skeleton is preferably in the range of 3% or more by mass to 50% or less by mass. If the content thereof is less than 3% by mass, the heat resistance due to the maleimide cannot be obtained, while if it is more than 50% by mass, transmittance thereof is insufficient so that the resin pattern to be obtained becomes brittle. In view of the above-mentioned, the content thereof is more preferably in the range of 5% or more by mass to 40% or less by mass, while especially preferably in the range of 10% or more by mass to 30% or less by mass.

Structure of the structure unit (A-1) derived from the maleimide is not particularly restricted provided that it is represented by the general formula (1).

Illustrative example of the maleimide which can be a raw material of the structure unit (A-1) includes: alkyl maleimides such as N-methyl maleimide, N-ethyl maleimide, N-propyl maleimide, N-isopropyl maleimide, N-butyl maleimide, N-isobutyl maleimide, N-2-methyl-2-propyl maleimide, N-pentyl maleimide, N-2-pentyl maleimide, N-3-pentyl maleimide, N-2-methyl-1-butyl maleimide, N-2-methyl-2-butyl maleimide, N-3-methyl-1-butyl maleimide, N-3-methyl-2-butyl maleimide, N-hexyl maleimide, N-2-hexyl maleimide, N-3-hexyl maleimide, N-2-methyl-1-pentyl maleimide, N-2-methyl-2-pentyl maleimide, N-2-methyl-3-pentyl maleimide, N-3-methyl-1-pentyl maleimide, N-3-methyl-2-pentyl maleimide, N-3-methyl-3-pentyl maleimide, N-4-methyl-1-pentyl maleimide, N-4-methyl-2-pentyl maleimide, N-2,2-dimethyl-1-butyl maleimide, N-3,3-dimethyl-1-butyl maleimide, N-3,3-dimethyl-2-butyl maleimide, N-2,3-dimethyl-1-butyl maleimide, N-2,3-dimethyl-2-butyl maleimide, N-hydroxymethyl maleimide, N-1-hydroxyethyl maleimide, N-2-hydroxyethyl maleimide, N-1-hydroxy-1-propyl maleimide, N-2-hydroxy-1-propyl maleimide, N-3-hydroxy-1-propyl maleimide, N-1-hydroxy-2-propyl maleimide, N-2-hydroxy-2-propyl maleimide, N-1-hydroxy-1-butyl maleimide, N-2-hydroxy-1-butyl maleimide, N-3-hydroxy-1-butyl maleimide, N-4-hydroxy-1-butyl maleimide, N-1-hydroxy-2-butyl maleimide, N-2-hydroxy-2-butyl maleimide, N-3-hydroxy-2-butyl maleimide, N-4-hydroxy-2-butyl maleimide, N-2-methyl-3-hydroxy-1-propyl maleimide, N-2-methy-3-hydroxy-2-propyl maleimide, N-2-methyl-2-hydroxy-1-propyl maleimide, N-1-hydroxy-1-pentyl maleimide, N-2-hydroxy-1-pentyl maleimide, N-3-hydroxy-1-pentyl maleimide, N-4-hydroxy-1-pentyl maleimide, N-5-hydroxy-1-pentyl maleimide, N-1-hydroxy-2-pentyl maleimide, N-2-hydroxy-2-pentyl maleimide, N-3-hydroxy-2-pentyl maleimide, N-4-hydroxy-2-pentyl maleimide, N-5-hydroxy-2-pentyl maleimide, N-1-hydroxy-3-pentyl maleimide, N-2-hydroxy-3-pentyl maleimide, N-3-hydroxy-3-pentyl maleimide, N-1-hydroxy-2-methyl-1-butyl maleimide, N-1-hydroxy-2-methyl-2-butyl maleimide, N-1-hydroxy-2-methyl-3-butyl maleimide, N-1-hydroxy-2-methyl-4-butyl maleimide, N-2-hydroxy-2-methyl-1-butyl maleimide, N-2-hydroxy-2-methyl-3-butyl maleimide, N-2-hydroxy-2-methyl-4-butyl maleimide, N-2-hydroxy-3-methyl-1-butyl maleimide, N-2-hydroxy-3-methyl-2-butyl maleimide, N-2-hydroxy-3-methyl-3-butyl maleimide, N-2-hydroxy-3-methyl-4-butyl maleimide, N-4-hydroxy-2-methyl-1-butyl maleimide, N-4-hydroxy-2-methyl-2-butyl maleimide, N-1-hydroxy-3-methyl-2-butyl maleimide, N-1-hydroxy-3-methyl-1-butyl maleimide, N-1-hydroxy-2,2-dimethyl-1-propyl maleimide, N-3-hydroxy-2,2-dimethyl-1-propyl maleimide, N-1-hydroxy-1-hexyl maleimide, N-1-hydroxy-2-hexyl maleimide, N-1-hydroxy-3-hexyl maleimide, N-1-hydroxy-4-hexyl maleimide, N-1-hydroxy-5-hexyl maleimide, N-1-hydroxy-6-hexyl maleimide, N-2-hydroxy-1-hexyl maleimide, N-2-hydroxy-2-hexyl maleimide, N-2-hydroxy-3-hexyl maleimide, N-2-hydroxy-4-hexyl maleimide, N-2-hydroxy-5-hexyl maleimide, N-2-hydroxy-6-hexyl maleimide, N-3-hydroxy-1-hexyl maleimide, N-3-hydroxy-2-hexyl maleimide, N-3-hydroxy-3-hexyl maleimide, N-3-hydroxy-4-hexyl maleimide, N-3-hydroxy-5-hexyl maleimide, N-3-hydroxy-6-hexyl maleimide, N-1-hydroxy-2-methyl-1-pentyl maleimide, N-1-hydroxy-2-methyl-2-pentyl maleimide, N-1-hydroxy-2-methyl-3-pentyl maleimide, N-1-hydroxy-2-methyl-4-pentyl maleimide, N-1-hydroxy-2-methyl-5-pentyl maleimide, N-2-hydroxy-2-methyl-1-pentyl maleimide, N-2-hydroxy-2-methyl-2-pentyl maleimide, N-2-hydroxy-2-methyl-3-pentyl maleimide, N-2-hydroxy-2-methyl-4-pentyl maleimide, N-2-hydroxy-2-methyl-5-pentyl maleimide, N-2-hydroxy-3-methyl-1-pentyl maleimide, N-2-hydroxy-3-methyl-2-pentyl maleimide, N-2-hydroxy-3-methyl-3-pentyl maleimide, N-2-hydroxy-3-methyl-4-pentyl maleimide, N-2-hydroxy-3-methyl-5-pentyl maleimide, N-2-hydroxy-4-methyl-1-pentyl maleimide, N-2-hydroxy-4-methyl-2-pentyl maleimide, N-2-hydroxy-4-methyl-3-pentyl maleimide, N-2-hydroxy-4-methyl-4-pentyl maleimide, N-2-hydroxy-4-methyl-5-pentyl maleimide, N-3-hydroxy-2-methyl-1-pentyl maleimide, N-3-hydroxy-2-methyl-2-pentyl maleimide, N-3-hydroxy-2-methyl-3-pentyl maleimide, N-3-hydroxy-2-methyl-4-pentyl maleimide, N-3-hydroxy-2-methyl-5-pentyl maleimide, N-1-hydroxy-4-methyl-1-pentyl maleimide, N-1-hydroxy-4-methyl-2-pentyl maleimide, N-1-hydroxy-4-methyl-3-pentyl maleimide, N-1-hydroxy-4-methyl, N-1-hydroxy-3-methyl-1-pentyl maleimide, N-1-hydroxy-3-methyl-2-pentyl maleimide, N-1-hydroxy-3-methyl-3-pentyl maleimide, N-1-hydroxy-3-methyl-4-pentyl maleimide, N-1-hydroxy-3-methyl-5-pentyl maleimide, N-3-hydroxy-3-methyl-1-pentyl maleimide, N-3-hydroxy-3-methyl-2-pentyl maleimide, N-1-hydroxy-3-ethyl-4-butyl maleimide, N-2-hydroxy-3-ethyl-4-butyl maleimide, N-2-hydroxy-2-ethyl-1-butyl maleimide, N-4-hydroxy-3-ethyl-1-butyl maleimide, N-4-hydroxy-3-ethyl-2-butyl maleimide, N-4-hydroxy-3-ethyl-3-butyl maleimide, N-4-hydroxy-3-ethyl-4-butyl maleimide, N-1-hydroxy-2,3-dimethyl-1-butyl maleimide, N-1-hydroxy-2,3-dimethyl-2-butyl maleimide, N-1-hydroxy-2,3-dimethyl-3-butyl maleimide, N-1-hydroxy-2,3-dimethyl-4-butyl maleimide, N-2-hydroxy-2,3-dimethyl-1-butyl maleimide, N-2-hydroxy-2,3-dimethyl-3-butyl maleimide, N-2-hydroxy-2,3-dimethyl-4-butyl maleimide, N-1-hydroxy-2,2-dimethyl-1-butyl maleimide, N-1-hydroxy-2,2-dimethyl-3-butyl maleimide, N-1-hydroxy-2,2-dimethyl-4-butyl maleimide, N-2-hydroxy-3,3-dimethyl-1-butyl maleimide, N-2-hydroxy-3,3-dimethyl-2-butyl maleimide, N-2-hydroxy-3,3-dimethyl-4-butyl maleimide, N-1-hydroxy-3,3-dimethyl-1-butyl maleimide, N-1-hydroxy-3,3-dimethyl-2-butyl maleimide, and N-1-hydroxy-3,3-dimethyl-4-butyl maleimide; cycloalkyl maleimides such as N-cyclopropyl maleimide, N-cyclobutyl maleimide, N-cyclopentyl maleimide, N-cyclohexyl maleimide, N-cycloheptyl maleimide, N-cyclooctyl maleimide, N-2-methylcyclohexyl maleimide, N-2-ethylcyclohexyl maleimide, and N-2-chlorocyclohexyl maleimide; and aryl maleimides such as N-phenyl maleimide, N-2-methylphenyl maleimide, N-2-ethylphenyl maleimide, and N-2-chlorophenyl maleimide.

Among them, in view of transparency and solubility, a cycloalkyl maleimide is preferably used, while N-cyclohexyl maleimide and N-2-methylcyclohexyl maleimide are more preferably used.

These compounds may be used singly or in a combination of two or more of them.

In the case that the alkaline-soluble (meth)acryl polymer having the maleimide skeleton in the main chain thereof is used as the (A) component, content of the structure unit (A-2) derived from the (meth)acrylate is preferably in the range of 20% or more by mass to 90% or less by mass. If the content thereof is less than 20% by mass, transparency derived from the (meth)acrylate cannot be obtained; and if the content thereof is more than 90% by mass, satisfactory heat resistance cannot be obtained. In view of the above-mentioned, the content thereof is more preferably in the range of 25% or more by mass to 85% or less by mass, while especially preferably in the range of 30% or more by mass to 80% or less by mass.

Structure of the structure unit (A-2) derived from the (meth)acrylate is not particularly restricted provided that it is represented by the general formula (2).

Illustrative example of the (meth)acrylate (which is a raw material of the structure unit (A-2) in a preferred embodiment) used in the (A) component of the present invention includes: aliphatic (meth)acrylates such as methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethylhexyl (meth)acrylate, heptyl (meth)acrylate, octyl (meth)acrylate, nonyl (meth)acrylate, decyl (meth)acrylate, undecyl (meth)acrylate, lauryl (meth)acrylate, tridecyl (meth)acrylate, tetradecyl (meth)acrylate, pentadecyl (meth)acrylate, hexadecyl (meth)acrylate, stearyl (meth)acrylate, behenyl (meth)acrylate, 2-hydroxyethyl (meth)acrylate, 2-hydroxypropyl (meth)acrylate, 3-chloro-2-hydroxypropyl (meth)acrylate, 2-hydroxybutyl (meth)acrylate, methoxypolyethylene glycol (meth)acrylate, ethoxypolyethylene glycol (meth)acrylate, methoxypolypropylene glycol (meth)acrylate, ethoxypolypropylene glycol (meth)acrylate, and mono(2-(meth)acryloyloxyethyl) succinate; alicyclic (meth)acrylates such as cyclopentyl (meth)acrylate, cyclohexyl (meth)acrylate, cyclopentyl (meth)acrylate, dicyclopentanyl (meth)acrylate, dicyclopentenyl (meth)acrylate, isobornyl (meth)acrylate, mono(2-(meth)acryloyloxyethyl) tetrahydrophthalate, and mono(2-(meth)acryloyloxyethyl) hexahydrophthalate; aromatic (meth)acrylates such as benzyl (meth)acrylate, phenyl (meth)acrylate, o-biphenyl (meth)acrylate, 1-naphthyl (meth)acrylate, 2-naphthyl (meth)acrylate, phenoxyethyl (meth)acrylate, p-cumylphenoxyethyl (meth)acrylate, o-phenylphenoxyethyl (meth)acrylate, 1-naphtoxyethyl (meth)acrylate, 2-naphthoxyethyl (meth)acrylate, phenoxypolyethylene glycol (meth)acrylate, nonylphenoxypolyethylene glycol (meth)acrylate, phenoxypolypropylene glycol (meth)acrylate, 2-hydroxy-3-phenoxypropyl (meth)acrylate, 2-hydroxy-3-(o-phenylphenoxy)propyl (meth)acrylate, 2-hydroxy-3-(1-naphthoxy)propyl (meth)acrylate, and 2-hydroxy-3-(2-naphthoxy)propyl (meth)acrylate; and heterocyclic (meth)acrylates such as 2-tetrahydrofurfuryl (meth)acrylate, N-(meth)acryloyloxyethyl hexahydrophthalimide, and 2-(meth)acryloyloxyethyl-N-carbazole, as well as the modified caprolactone thereof.

Among them, in view of transparency and heat resistance, aliphatic (meth)acrylates such as methyl (meth)acrylate, ethyl (meth)acrylate, butyl (meth)acrylate, and 2-ethylhexyl (meth)acrylate; the above-mentioned alicyclic (meth)acrylates; the above-mentioned aromatic (meth)acrylates; and the above-mentioned heterocyclic (meth)acrylates are preferable.

These compounds may be used singly or in a combination of two or more of them.

In the alkaline-soluble (meth)acryl polymer, content of the structure units (A-3) and (A-4) derived from the compounds having the carboxyl group and the unsaturated ethylenic double bond is preferably in the range of 3% or more by mass to 60% or less by mass. If the content thereof is less than 3% by mass, dissolution into a developing solution comprising the alkaline aqueous solution and so forth is difficult, while if the content thereof is more than 60% by mass, resistance to the developing solution (property that the pattern portion not removed by development is not damaged by the developing solution) deteriorates in the later-mentioned developing step in which the layer of the photosensitive resin composition is selectively removed thereby forming the pattern by development. In view of the above-mentioned, the content thereof is more preferably in the range of 5% or more by mass to 50% or less by mass, while especially preferably in the range of 10% or more by mass to 40% or less by mass.

Structures of the structure units (A-3) and (A4) derived from the compound having the carboxyl group and the ethylenic unsaturated group are not particularly restricted provided that the structures are represented by the general formulae (3) and (4).

Preferable example of the compound which has the carboxyl group and the ethylenic unsaturated group and is the raw material of the structure unit (A-3) includes (meth)acrylic acid, maleic acid, fumaric acid, crotonic acid, itaconic acid, citraconic acid, mesaconic acid, and cinnamic acid. Among them, in view of transparency and alkaline-solubility, (meth)acrylic acid, maleic acid, fumaric acid, and crotonic acid are preferable.

Also, by using maleic anhydride as the raw material, the ring thereof may be opened after polymerization by an appropriate alcohol such as methanol, ethanol, and propanol thereby changing to the structure shown by the structure unit (A-3). These compounds may be used singly or in a combination of two or more of them.

Illustrative example of the compound which has the carboxyl group and the ethylenic unsaturated group and is the raw material of the structure unit (A-4) includes mono(2-(meth)acryloyloxyethyl) succinate, mono(2-(meth)acryloyloxyethyl) phthalate, mono(2-(meth)acryloyloxyethyl) isophthalate, mono(2-(meth)acryloyloxyethyl) terephthalate, mono(2-(meth)acryloyloxyethyl) tetrahydrophthalate, mono(2-(meth)acryloyloxyethyl) hexahydrophthalate, mono(2-(meth)acryloyloxyethyl) hexahydroisophthalate, mono(2-(meth)acryloyloxyethyl) hexahydroterephthalate, ω-carboxy-polycaprolactone mono(meth)acrylate, 3-vinyl benzoic acid, and 4-vinyl benzoic acid.

Among them, in view of transparency and alkaline-solubility, mono(2-(meth)acryloyloxyethyl) succinate, mono(2-(meth)acryloyloxyethyl) tetrahydrophthalate, mono(2-(meth)acryloyloxyethyl) hexahydrophthalate, mono(2-(meth)acryloyloxyethyl) hexahydroisophthalate, and mono(2-(meth)acryloyloxyethyl) hexahydroterephthalate are preferable.

These compounds may be used singly or in a combination of two or more of them.

Also, the alkaline-soluble (meth)acryl polymer may contain a structure unit other than the structure units (A-1) to (A-4), if the need arises.

As to the compound having an ethylenic unsaturated group which is the raw material of the structure unit like this, there is no particular restriction in it and therefore, illustrative example thereof includes styrene, α-methyl styrene, vinyl toluene, vinyl chloride, vinyl acetate, vinyl pyridine, N-vinyl pyrrolidone, N-vinyl carbazole, butadiene, isoprene, and chloroprene. Among them, in view of heat resistance and transparency, styrene, α-methyl styrene, vinyl toluene, and N-vinyl carbazole are more preferably used.

These compounds may be used singly or in a combination of two or more of them.

As to the synthesis method of the alkaline-soluble (meth)acryl polymer, there is no particular restriction in it; and for example, this polymer may be obtained by copolymerizing a maleimide which is a raw material of the structure unit (A-1), a (meth)acrylate which is a raw material of the structure unit (A-2), a compound having a carboxyl group and an ethylenic unsaturated group which is a raw material of the structure unit (A-3) and/or the structure unit (A-4), and if the need arises, other compound having an ethylenic unsaturated group, by using a suitable polymerization initiator (preferably a radial polymerization initiator). At this time an organic solvent may be used as a reaction solvent, if the need arises.

As to the polymerization initiator used in the present invention, there is no particular restriction in it; and therefore, illustrative example thereof includes: ketone peroxides such as methyl ethyl ketone peroxide, cyclohexanone peroxide, and methylcyclohexanone peroxide; peroxy ketals such as 1,1-bis(t-butylperoxy) cyclohexane, 1,1-bis(t-butylperoxy)-2-methyl cyclohexane, 1,1-bis(t-butylperoxy)-3,3,5-trimethylcyclohexane, 1,1-bis(t-hexylperoxy) cyclohexane, and 1,1-bis(t-hexylperoxy)-3,3,5-trimethylcyclohexane; hydroperoxides such as p-menthane hydroperoxide; dialkyl peroxides such as α,α′-bis(t-butylperoxy) diisopropylbenzene, dicumyl peroxide, t-butylcumyl peroxide, and di-t-butyl peroxide; diacyl peroxides such as octanoyl peroxide, lauroyl peroxide, stearyl peroxide, and benzoyl peroxide; peroxy carbonates such as bis(4-t-butylcyclohexyl)peroxy dicarbonate, di-2-ethoxyethylperoxy dicarbonate, di-2-ethylhexylperoxy dicarbonate, and di-3-methoxybutylperoxy carbonate; peroxy esters such as t-butylperoxy pivalate, t-hexylperoxy pivalate, 1,1,3,3-tetramethylbutylperoxy-2-ethyl hexanoate, 2,5-dimethyl-2,5-bis(2-ethylhexanoylperoxy)hexane, t-hexylperoxy-2-ethyl hexanoate, t-butylperoxy-2-ethyl hexanoate, t-butylperoxy isobutyrate, t-hexylperoxyisopropyl monocarbonate, t-butylperoxy-3,5,5-trimethyl hexanoate, t-butylperoxy laurylate, t-butylperoxyisopropyl monocarbonate, t-butylperoxy-2-ethylhexyl monocarbonate, t-butylperoxy benzoate, t-hexylperoxy benzoate, 2,5-dimethyl-2,5-bis(benzoylperoxy)hexane, and t-butylperoxy acetate; and azo compounds such as 2,2′-azobisisobutyronitrile, 2,2′-azobis(2,4-dimethylvaleronitrile), and 2,2′-azobis(4-methoxy-2′-dimethylvaleronitrile).

As to the organic solvent to be used as the reaction solvent, there is no particular restriction in it, provided that it can dissolve the alkaline-soluble polymer; and therefore, illustrative example thereof includes: aromatic hydrocarbons such as toluene, xylene, mesitylene, cumene, and p-cymene; cyclic ethers such as tetrahydrofuran and 1,4-dioxane; alcohols such as methanol, ethanol, isopropanol, butanol, ethylene glycol, and propylene glycol; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, and γ-butyrolacone; carbonate esters such as ethylene carbonate and propylene carbonate; polyvalent alcohol alkyl ethers such as ethylene glycol monomethyl ether, ethylene glycol monoethyl ether, ethylene glycol monobutyl ether, ethylene glycol dimethyl ether, ethylene glycol diethyl ether, propylene glycol monomethyl ether, propylene glycol monoethyl ether, propylene glycol dimethyl ether, propylene glycol diethyl ether, diethylene glycol monomethyl ether, diethylene glycol monoethyl ether, diethylene glycol monobutyl ether, diethylene glycol dimethyl ether, and diethylene glycol diethyl ether; polyvalent alcohol alkyl ether acetates such as ethylene glycol monomethyl ether acetate, ethylene glycol monoethyl ether acetate, ethylene glycol monobutyl ether acetate, propylene glycol monomethyl ether acetate, propylene glycol monoethyl ether acetate, diethylene glycol monomethyl ether acetate, and diethylene glycol monoethyl ether acetate; and amides such as N,N-dimethyl formamide, N,N-dimethyl acetamide, and N-methylpyrrolidone.

These organic solvents may be used singly or in a combination of two or more of them.

Also, the alkaline-soluble (meth)acryl polymer may contain, as the need arises, an ethylenic unsaturated group in the side chain thereof. For example, the ethylenic unsaturated group may be introduced into the side chain of the alkaline-soluble (meth)acryl polymer mentioned above by carrying out an addition reaction with a compound having at least one ethylenic unsaturated group and one functional group selected from an epoxy group, an oxetanyl group, an isocyanate group, a hydroxyl group, a carboxyl group, and the like.

As to these compounds, there is no particular restriction in it; and therefore, illustrative example thereof includes: compounds having an ethylenic unsaturated group and an epoxy group, such as glycidyl (meth)acrylate, α-ethylglycidyl (meth)acrylate, α-propylglycidyl (meth)acrylate, α-butylglycidyl (meth)acrylate, 2-methylglycidyl (meth)acrylate, 2-ethylglycidyl (meth)acrylate, 2-propylglycidyl (meth)acrylate, 3,4-epoxybutyl (meth)acrylate, 3,4-epoxyheptyl (meth)acrylate, α-ethyl-6,7-epoxyheptyl (meth)acrylate, 3,4-epoxycyclohexylmethyl (meth)acrylate, o-vinylbenzyl glycidyl ether, m-vinylbenzyl glycidyl ether, and p-vinylbenzyl glycidyl ether; compounds having an ethylenic unsaturated group and an oxetanyl group, such as (2-ethyl-2-oxetanyl)methyl (meth)acrylate, (2-methyl-2-oxetanyl)methyl (meth)acrylate, 2-(2-ethyl-2-oxetanyl)ethyl (meth)acrylate, 2-(2-methyl-2-oxetanyl)ethyl (meth)acrylate, 3-(2-ethyl-2-oxetanyl)propyl (meth)acrylate, and 3-(2-methyl-2-oxetanyl)propyl (meth)acrylate; compounds having an ethylenic unsaturated group and an isocyanate group such as 2-(meth)acryloyloxyethyl isocyanate; compounds having an ethylenic unsaturated group and a hydroxyl group such as 2-hydroxyethyl (meth)acrylate, 2-hydroxypropyl (meth)acrylate, 3-chloro-2-hydroxypropyl (meth)acrylate, and 2-hydroxybutyl (meth)acrylate; and compounds having an ethylenic unsaturated group and a carboxyl group such as (meth)acrylic acid, crotonic acid, cinnamic acid, succinic acid (2-(meth)acryloyloxyethyl), 2-phthaloylethyl (meth)acrylate, 2-tetrahydrophthaloylethyl (meth)acrylate, 2-hexahydrophthaloylethyl (meth)acrylate, ω-carboxy-polycaprolactone mono(meth)acrylate, 3-vinyl benzoic acid, and 4-vinyl benzoic acid.

Among them, in view of transparency and reactivity, glycidyl (meth)acrylate, 3,4-epoxycyclohexylmethyl (meth)acrylate, ethyl isocyanate (meth)acrylate, 2-hydroxyethyl (meth)acrylate, 2-hydroxypropyl (meth)acrylate, 2-hydroxybutyl (meth)acrylate, (meth)acrylic acid, crotonic acid, and 2-hexahydrophthaloylethyl (meth)acrylate are preferable. These compounds may be used singly or in a combination of two or more of them.

The weight-average molecular weight of the (A) alkaline-soluble polymer is preferably in the range of 1,000 or more to 300,000 or less. If the molecular weight thereof is less than 1,000, strength of the cured product of the resin composition is insufficient because the molecular weight thereof is too large, while if the molecular weight thereof is larger than 300,000, the curved shape by heat sagging cannot be obtained sufficiently well, and also solubility into a developing solution of an alkaline aqueous solution as well as compatibility with the (B) polymerizable compound is insufficient. In view of the above-mentioned, the molecular weight thereof is more preferably in the range of 3,000 or more to 200,000 or less, while especially preferably in the range of 5,000 or more to 100,000 or less.

Meanwhile, the weight-average molecular weight in the present invention is measured by a gel-permeation chromatography (GPC), and the measured value converted to the value of the standard polystyrene is used.

Acid value of the alkaline-soluble (meth)acrylate polymer can be determined such that it may be developed by various publicly known developing solutions in the process to form a pattern by selectively removing a layer of the photosensitive resin composition by the development which will be mentioned later. In the case that the development is made by using an alkaline aqueous solution of for example, sodium carbonate, potassium carbonate, tetramethylammonium hydroxide, and triethanolamine, the acid value thereof is preferably in the range of 20 mg-KOH/g or more to 300 mg-KOH/g or less. If the acid value is less than 20 mg-KOH/g, development is difficult, while if the acid value is more than 300 mg-KOH/g, resistance to the developing solution becomes lower. In view of the above-mentioned, the acid value is more preferably in the range of 30 mg-KOH/g or more to 250 mg-KOH/g or less, while especially preferably in the range of 40 mg-KOH/g or more to 200 mg-KOH/g or less.

In the case that development is done by using an alkaline aqueous solution comprising water or an alkaline aqueous solution and one or more surfactant, the acid value is preferably in the range of 10 mg-KOH/g or more to 260 mg-KOH/g or less. If the acid value is less than 10 mg-KOH/g, development is difficult, while if the acid value is more than 260 mg-KOH/g, resistance to the developing solution becomes lower. In view of the above-mentioned, the acid value is more preferably in the range of 20 mg-KOH/g or more to 250 mg-KOH/g or less, while especially preferably in the range of 30 mg-KOH/g or more to 200 mg-KOH/g or less.

Blending amount of the (A) component is preferably in the range of 10% or more by mass to 85% or less by mass relative to total amount of the (A) component and the (B) component. If the amount is less than 10% by mass, strength of the cured product of the photosensitive resin composition for forming a member having a curved shape or the flexibility thereof is sometimes insufficient, while if the blending amount is more than 85% by mass, the (A) component is entangled by the (B) component at the time of exposure, so that it cannot be readily cured, thereby occasionally leading to insufficient resistance to the developing solution. In view of the above-mentioned, the blending amount is more preferably 15% or more by mass, while especially preferably 20% or more by mass. Also, the upper limit value thereof is more preferably 75% or less by mass, while especially preferably 65% or less by mass. In addition, the range of 20% or more by mass to 65% or less by mass is an excellent range especially in order to express the curved shape by a heat treatment.

### (B) Component:

As to the polymerizable compound of the (B) component having a thermally reactive group, compounds having one epoxy group and one ethylenic unsaturated group in one molecule is preferable.

Compound like this may be exemplified by an epoxy (meth)acrylate obtained by reacting an epoxy resin having a glycidyl group within one molecule with a (meth)acrylic acid compound, wherein the product obtained by reacting the (meth)acrylic compound with the epoxy resin with the equivalent of the former to the epoxy group being in the range of 0.1 or more to 0.9 or less is preferable, while more preferably in the range of 0.2 or more to 0.8 or less. The equivalent thereof is especially preferable in the range of 0.4 or more to 0.6 or less.

Specific example thereof includes; bifunctional phenol glycidyl ethers such as a bisphenol A type epoxy (meth)acrylate, a tetrabromobisphenol A type epoxy (meth)acrylate, a bisphenol F type epoxy (meth)acrylate, a bisphenol AF type epoxy (meth)acrylate, a bisphenol AD type epoxy (meth)acrylate, a biphenyl type epoxy (meth)acrylate, a naphthalene type epoxy (meth)acrylate, and a fluorene type epoxy (meth)acrylate; derivatives of hydrogenated bifunctional phenol glycidyl ethers such as a hydrogenated bisphenol A type epoxy (meth)acrylate, a hydrogenated bisphenol F type epoxy (meth)acrylate, a hydrogenated 2,2′-biphenol type epoxy (meth)acrylate, and a hydrogenated 4,4′-biphenol type epoxy (meth)acrylate; derivatives of polyfunctional phenol glycidyl ethers such as a phenol novolak type epoxy (meth)acrylate, a cresol novolak type epoxy (meth)acrylate, a dicyclopentadiene-phenol type epoxy (meth)acrylate, and a tetraphenolethane type epoxy (meth)acrylate; derivatives of bifunctional aliphatic alcohol glycidyl ethers such as a polyethylene glycol type epoxy (meth)acrylate, a polypropylene glycol type epoxy (meth)acrylate, a neopentyl glycol type epoxy (meth)acrylate, and a 1,6-hexanediol type epoxy (meth)acrylate; derivatives of bifunctional alicyclic alcohol glycidyl ethers such as a cyclohexanedimethanol type epoxy (meth)acrylate and a tricyclodecanedimethanol type epoxy (meth)acrylate; derivatives of polyfunctional aliphatic alcohol glycidyl ethers such as a trimethylolpropane type epoxy (meth)acrylate, a sorbitol type epoxy (meth)acrylate, and a glycerin type epoxy (meth)acrylate; derivatives of polyfunctional aromatic glycidyl esters such as diglycidyl phthalate ester; and epoxy acrylates derived from bifunctional alicyclic glycidyl esters such as diglycidyl tetrahydrophthalate ester and diglycidyl hexahydrophthalate ester.

Among them, in view of transparency, high refractive index, and high heat resistance, epoxy (meth)acrylates having an alicyclic ring or an aromatic ring such as a bisphenol A type epoxy (meth)acrylate, a bisphenol F type epoxy (meth)acrylate, a bisphenol AF type epoxy (meth)acrylate, a bisphenol AD type epoxy (meth)acrylate, a biphenyl type epoxy (meth)acrylate, a naphthalene type epoxy (meth)acrylate, a fluorene type epoxy (meth)acrylate, a phenol novolak type epoxy (meth)acrylate, a cresol novolak type epoxy (meth)acrylate, a cyclohexanedimethanol type epoxy (meth)acrylate, and a tricyclodecanedimethanol type epoxy (meth)acrylate are preferable. Among them, compounds having a bisphenol skeleton within the molecule thereof are especially preferable.

In view of development and heat resistance, the polymerizable compound of the (B) component contains, in addition to the compound having an epoxy group and an ethylenic unsaturated group in one molecule, preferably at least any one of a compound having two or more ethylenic unsaturated groups in one molecule and a compound having two or more epoxy groups in one molecule.

Meanwhile, in the composition of the present invention, there is a case that the compound having an epoxy group and an unsaturated ethylenic group is not contained therein.

Illustrate example of the compound having two or more ethylenic unsaturated groups in one molecule includes a (meth)acrylate, a halogenated vinylidene, a vinyl ether, a vinyl ester, a vinyl pyridine, a vinyl amide, and an arylated vinyl, wherein in view of transparency, a (meth)acrylate and an arylated vinyl are preferable. As to the (meth)acrylate, any of bifunctional and polyfunctional compounds may be used.

Illustrative example of the bifunctional (meth)acrylate includes: aliphatic (meth)acrylates such as ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, dipropylene glycol di(meth)acrylate, tripropylene glycol di(meth)acrylate, tetrapropylene glycol di(meth)acrylate, polypropylene glycol di(meth)acrylate, ethoxylated propylene glycol di(meth)acrylate, 1,3-butanediol di(meth)acrylate, 1,4-butanediol di(meth)acrylate, neopentyl glycol di(meth)acrylate, 3-methyl-1,5-pentanediol di(meth)acrylate, 1,6-hexane diol di(meth)acrylate, 2-butyl-2-ethyl-1,3-propanediol di(meth)acrylate, 1,9-nonane diol di(meth)acrylate, 1,10-decanediol di(meth)acrylate, glycerin di(meth)acrylate, tricyclodecanedimethanol (meth)acrylate, and ethoxylated 2-methyl-1,3-propane diol di(meth)acrylate; alicyclic (meth)acrylate such as cyclohexanedimethanol (meth)acrylate, ethoxylated cyclohexanedimethanol (meth)acrylate, propoxylated cyclohexanedimethanol (meth)acrylate, ethoxylated propoxylated cyclohexanedimethanol (meth)acrylate, tricyclodecanedimethanol (meth)acrylate, ethoxylated tricyclodecanedimethanol (meth)acrylate, propoxylated tricyclodecanedimethanol (meth)acrylate, ethoxylated propoxylated tricyclodecanedimethanol (meth)acrylate, ethoxylated hydrogenated bisphenol A di(meth)acrylate, propoxylated hydrogenated bisphenol A di(meth)acrylate, ethoxylated propoxylated hydrogenated bisphenol A di(meth)acrylate, ethoxylated hydrogenated bisphenol F di(meth)acrylate, propoxylated hydrogenated bisphenol F di(meth)acrylate, and ethoxylated propoxylated hydrogenated bisphenol F di(meth)acrylate; aromatic (meth)acrylates such as ethoxylated bisphenol A di(meth)acrylate, propoxylated bisphenol A di(meth)acrylate, ethoxylated propoxylated bisphenol A di(meth)acrylate, ethoxylated bisphenol F di(meth)acrylate, propoxylated bisphenol F di(meth)acrylate, ethoxylated propoxylated bisphenol F di(meth)acrylate, ethoxylated bisphenol AF di(meth)acrylate, propoxylated bisphenol AF di(meth)acrylate, ethoxylated propoxylated bisphenol AF di(meth)acrylate, an ethoxylated fluorene type di(meth)acrylate, an propoxylated fluorene type di(meth)acrylate, and an ethoxylated propoxylated fluorene type di(meth)acrylate; heterocyclic (meth)acrylates such as ethoxylated isocyanuric acid di(meth)acrylate, propoxylated isocyanuric acid di(meth)acrylate, and ethoxylated propoxylated isocyanuric acid di(meth)acrylate; caprolacone-modified compounds of them; aliphatic epoxy (meth)acrylates such as a neopentyl type epoxy (meth)acrylate; alicyclic epoxy (meth)acrylates such as a cyclohexanedimethanol type epoxy (meth)acrylate, a hydrogenated bisphenol A type epoxy (meth)acrylate, and a hydrogenated bisphenol F type epoxy (meth)acrylate; and aromatic epoxy (meth)acrylates such as a resorcinol type epoxy (meth)acrylate, a bisphenol A type epoxy (meth)acrylate, a bisphenol F type epoxy (meth)acrylate, a bisphenol AF type epoxy (meth)acrylate, and a fluorene type epoxy (meth)acrylate.

Among them, in view of transparency and heat resistance, the above-mentioned alicyclic (meth)acrylates, the above-mentioned aromatic (meth)acrylates, the above-mentioned heterocyclic (meth)acrylates, the above-mentioned alicyclic epoxy (meth)acrylates, and the above-mentioned aromatic epoxy (meth)acrylates are preferable.

Illustrative example of the polyfunctional (meth)acrylates having 3 or more functional groups includes: aliphatic (meth)acrylates such as trimethylolpropane tri(meth)acrylate, ethoxylated trimethylolpropane tri(meth)acrylate, propoxylated trimethylolpropane tri(meth)acrylate, ethoxylated propoxylated trimethylolpropane tri(meth)acrylate, pentaerythritol tri(meth)acrylate, ethoxylated pentaerythritol tri(meth)acrylate, propoxylated pentaerythritol tri(meth)acrylate, ethoxylated propoxylated pentaerythritol tri(meth)acrylate, pentaerythritol tetra(meth)acrylate, ethoxylated pentaerythritol tetra(meth)acrylate, propoxylated pentaerythritol tetra(meth)acrylate, ethoxylated propoxylated pentaerythritol tetra(meth)acrylate, ditrimethylolpropane tetraacrylate, and dipentaerythritol hexa(meth)acrylate; heterocyclic (meth)acrylates such as ethoxylated isocyanuric acid tri(meth)acrylate, propoxylated isocyanuric acid tri(meth)acrylate, and ethoxylated propoxylated isocyanuric acid tri(meth)acrylate; caprolactone-modified compounds of them; and aromatic epoxy (meth)acrylates such as a phenol novolak type epoxy (meth)acrylate and a cresol novolak type epoxy (meth)acrylate.

Among them, in view of transparency and heat resistance, heterocyclic (meth)acrylates and aromatic epoxy (meth)acrylates are preferable.

These compounds may be used singly or in a combination of two or more of them; and moreover, they may be used in a combination with other polymerizable compound.

In the case that a compound having an ethylenic unsaturated group is used, the content thereof is in the range of 10 or more parts by mass to 90 or less parts by mass, while more preferably in the range of 30 or more parts by mass to 80 or less parts by mass, relative to 100 parts by mass as the total mass of the polymerizable compounds in the (B) component. Especially preferable range is 40 or more parts by mass to 70 or less parts by mass.

If the compound having two or more epoxy groups in one molecule is incorporated therein, this compound undergoes a so-called epoxycarboxylation reaction with a carboxyl group derived from the alkaline-soluble (meth)acryl polymer of the (A) component to cause crosslinking between them; and as a result of it, heat resistance and strength are enhanced. Both a bifunctional compound and a polyfunctional compound may be used.

Specific example thereof includes; bifunctional phenol glycidyl ethers such as a bisphenol A type epoxy resin, a tetrabromobisphenol A type epoxy resin, a bisphenol F type epoxy resin, a bisphenol AF type epoxy resin, a bisphenol AD type epoxy resin, a biphenyl type epoxy resin, a naphthalene type epoxy resin, and a fluorene type epoxy resin; hydrogenated bifunctional phenol glycidyl ethers such as a hydrogenated bisphenol A type epoxy resin, a hydrogenated bisphenol F type epoxy resin, a hydrogenated 2,2′-biphenol type epoxy resin, and a hydrogenated 4,4′-biphenol type epoxy resin; polyfunctional phenol glycidyl ethers such as a phenol novolak type epoxy resin, a cresol novolak type epoxy resin, a dicyclopentadiene-phenol type epoxy resin, and a tetraphenolethane type epoxy resin; bifunctional aliphatic alcohol glycidyl ethers such as a polyethylene glycol type epoxy resin, a polypropylene glycol type epoxy resin, a neopentyl glycol type epoxy resin, and a 1,6-hexanediol type epoxy resin; bifunctional alicyclic alcohol glycidyl ethers such as a cyclohexanedimethanol type epoxy resin and a tricyclodecanedimethanol type epoxy resin; polyfunctional aliphatic alcohol glycidyl ethers such as a trimethylolpropane type epoxy resin, a sorbitol type epoxy resin, and a glycerin type epoxy resin; bifunctional aromatic glycidyl esters such as diglycidyl phthalate ester; bifunctional alicyclic glycidyl esters such as diglycidyl tetrahydrophthalate ester and diglycidyl hexahydrophthalate ester; bifunctional aromatic glycidyl diamines such as N,N-diglycidyl aniline and N,N-diglycidyl trifluoromethylaniline; polyfunctional aromatic glycidyl diamines such as N,N,N′,N′-tetraglycidyl-4,4-diaminodiphenylmethane, 1,3-bis(N,N-glycidylaminomethyl)cyclohexane, and N,N,O-triglycidyl-p-aminophenol; bifunctional alicyclic epoxy resins such as alicyclic diepoxy acetal, alicyclic diepoxy adipate, alicyclic diepoxy carboxylate, and vinyl cyclohexene dioxide; polyfunctional alicyclic epoxy resins such as additive of 2,2-bis(hydroxymethyl)-1-butanol with 1,2-epoxy-4-(2-oxiranyl)cyclohexane; polyfunctional heterocyclic epoxy resins such as triglycidyl isocyanurate; and bifunctional or polyfunctional silicon-containing epoxy resins such as an organopolysiloxane type epoxy resin.

Among them, in view of transparency and heat resistance, bifunctional phenol glycidyl ethers such as a bisphenol A type epoxy resin, a bisphenol F type epoxy resin, a bisphenol AF type epoxy resin, a bisphenol AD type epoxy resin, a biphenyl type epoxy resin, a naphthalene type epoxy resin, and a fluorene type epoxy resin; the above-mentioned hydrogenated bifunctional phenol glycidyl ethers; the above-mentioned polyfunctional phenol glycidyl ethers; the above-mentioned bifunctional alicyclic alcohol glycidyl ethers; the above-mentioned bifunctional aromatic glycidyl esters; the above-mentioned bifunctional alicyclic glycidyl esters; the above-mentioned bifunctional alicyclic epoxy resins; the above-mentioned polyfunctional alicyclic epoxy resins; the above-mentioned polyfunctional heterocyclic epoxy resins; and the above-mentioned bifunctional or polyfunctional silicon-containing epoxy resins are preferable.

These compounds may be used singly or in a combination of two or more of them; and in addition, they may be used in a combination with other polymerizable compound.

In addition, as the polymerizable compound of the (B) component, in view of heat resistance, it is preferable to use further one or more compound having an ethylenic unsaturated group as well as at least one group selected from the group consisting of an alicyclic structure, an aryl group, an aryloxy group, and an aralkyl group in one molecule. Specifically, a (meth)acrylate or an N-vinyl carbazole, both having at least one group selected from the group consisting of an alicyclic structure, an aryl group, an aryloxy group, and an aralkyl group, may be mentioned. Meanwhile, the aryl group represents, for example, aromatic hydrocarbon groups such as a phenyl group and a naphthyl group and aromatic heterocyclic groups such as a carbazole group.

Meanwhile, in the composition of the present invention, there is a case that the above-mentioned compound is used as the polymerizable compound of the (B) component without containing the compound having an epoxy group and an ethylenic unsaturated group.

More specifically, as the polymerizable compound of the (B) component, it is preferable to use at least one compound shown by the following general formulae (5) to (8). Or alternatively, as the polymerizable compound of the (B) component, it is also a preferable embodiment to use at least one compound selected from compounds having an aryl group and an ethylenic unsaturated group as shown by the following general formulae (5) to (8).

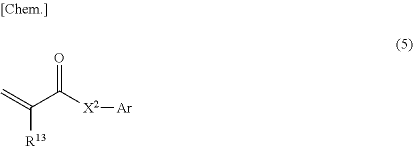

(In the formula, Ar represents any groups shown below;

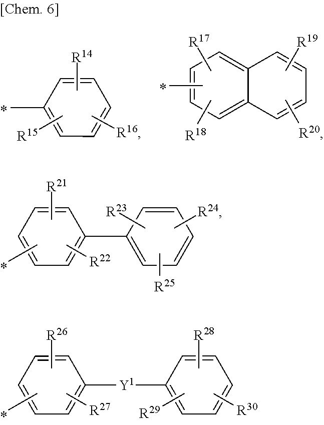

X² represents any divalent groups selected from O (oxygen atom), S (sulfur atom), OCH₂, SCH₂, O(CH₂CH₂O)ₐ, O[CH₂CH(CH₃)O]_{b}, and OCH₂CH(OH)CH₂O; and
Y¹ represents any divalent groups shown below (bonding chain is in the right and left of each structure);

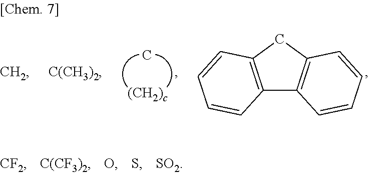

R¹³ represents any of a hydrogen atom and a methyl group; R¹⁴ to R³⁰ each independently represents any of a hydrogen atom, a fluorine atom, an organic group having 1 to 20 carbon atoms, and a fluorine-containing organic group having 1 to 20 carbon atoms; “a” and “b” each independently represents an integer of 1 to 20; and “c” represents an integer of 2 to 10.)

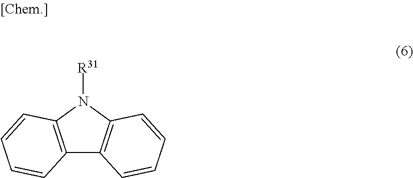

(In the formula, R³¹ represents any of the following groups;

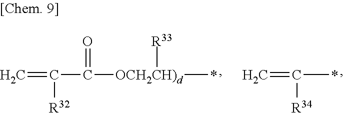

R³² to R³⁴ each independently represents any of a hydrogen atom and a methyl group;
and “d” represents an integer of 1 to 10.)

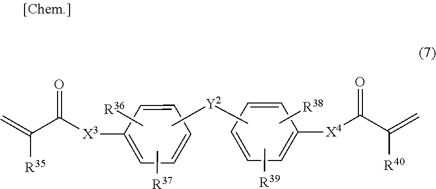

(In the formula, X³ and X⁴ each independently represents any divalent group selected from O, S, O(CH₂CH₂O)ₑ, and O[CH₂CH(CH₃)O]_{f};
Y2 represents any divalent groups shown below (bonding chain is in the right and left of each structure;

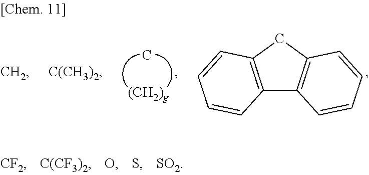

R³⁵ and R⁴⁰ each independently represents any of a hydrogen atom and a methyl group; R³⁶ to R³⁹ each independently represents any of a hydrogen atom, a fluorine atom, an organic group having 1 to 20 carbon atoms, and a fluorine-containing organic group having 1 to 20 carbon atoms; “e” and “f” each independently represents an integer of 1 to 20; and “g” represents an integer of 2 to 10.)

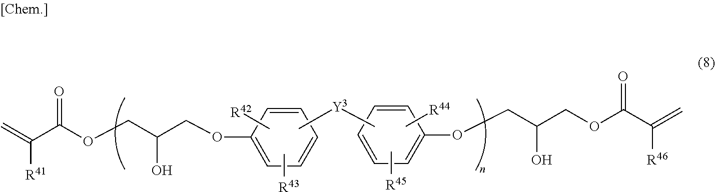

(In the formula, Y³ represents any divalent groups shown below (bonding chain is in the right and left of each structure);

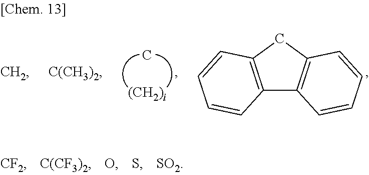

R⁴¹ and R⁴⁶ each independently represents any of a hydrogen atom and a methyl group; R⁴² to R⁴⁵ each independently represents any of a hydrogen atom, a fluorine atom, an organic group having 1 to 20 carbon atoms, and a fluorine-containing organic group having 1 to 20 carbon atoms; “h” represents an integer of 1 to 5; and “i” represents an integer of 2 to 10.)

Meanwhile, the organic groups in the general formulae (5) to (8) are exemplified by the same groups explained in the general formulae (1) to (4).

Blending amount of the polymerizable compound of the (B) component is preferably in the range of 15% or more by mass to 90% or less by mass relative to total amount of the (A) component and the (B) component. If this amount is less than 15% by mass, curing of the (A) alkaline-soluble (meth)acryl polymer by entangling therein becomes difficult, so that insufficient resistance to the developing solution may be occasionally resulted. On the other hand, if the amount is more than 90% by mass, sufficient film strength and flexibility in the cured film cannot be obtained occasionally. In view of the above-mentioned, the amount thereof is more preferably in the range of 30% or more by mass to 80% or less by mass.

### (C) Component:

As to the polymerization initiator of the (C) component, there is no particular restriction in it, provided that it can initiate the polymerization by heating or exposure to a UV beam and the like. For example, in the case that a compound having an ethylenic unsaturated group is used as the polymerizable compound of the (B) component, a thermal radical polymerization initiator, a photo radical polymerization initiator, and the like may be mentioned; however, a photo radical polymerization initiator is preferable because with it, the curing rate is fast, and curing can be done at a normal temperature.

Illustrative example of the thermal radical polymerization initiator includes: ketone peroxides such as methyl ethyl ketone peroxide, cyclohexanone peroxide, and methyl cyclohexanone peroxide; peroxyketals such as 1,1-bis(t-butylperoxy)cyclohexane, 1,1-bis(t-butylperoxy)-2-methylcyclohexane, 1,1-bis(t-butylperoxy)-3,3,5-trimethylcyclohexane, 1,1-bis(t-hexylperoxy)cyclohexane, and 1,1-bis(t-hexylperoxy)-3,3,5-trimethylcyclohexane; hydroperoxides such as p-menthane hydroperoxide; dialkyl peroxides such as α,α′-bis(t-butylperoxy) diisopropyl benzene, dicumyl peroxide, t-butyl cumyl peroxide, and di-t-butyl peroxide: diacyl peroxides such as octanoyl peroxide, lauroyl peroxide, stearyl peroxide, and benzoyl peroxide; peroxycarbonates such as bis(4-t-butylcyclohexyl)peroxy dicarbonate, di-2-ethoxyethylperoxy dicarbonate, di-2-ethylhexylperoxy dicarbonate, and di-3-methoxybutylperoxy carbonate; peroxy esters such as t-butylperoxy pivalate, t-hexylperoxy pivalate, 1,1,3,3-tetramethylbutylperoxy-2-ethylhexanoate, 2,5-dimethyl-2,5-bis(2-ethylhexanoylperoxy)hexane, t-hexylperoxy-2-ethylhexanoate, t-butylperoxy-2-ethylhexanoate, t-butylperoxy isobutyrate, t-hexylperoxy isopropyl monocarbonate, t-butylperoxy-3,5,5-trimethylhexanoate, t-butylperoxy laurylate, t-butylperoxy isopropyl monocarbonate, t-butylperoxy-2-ethylhexyl monocarbonate, t-butylperoxy benzoate, t-hexylperoxy benzoate, 2,5-dimethyl-2,5-bis(benzoylperoxy)hexane, and t-butylperoxy acetate; and azo compounds such as 2,2′-azobisisobutyronitrile, 2,2′-azobis(2,4-dimethylvaleronitrile), and 2,2′-azobis(4-methoxy-2′-dimethylvaleronitrile).

Among them, in view of curing properties, transparency, and heat resistance, the above-mentioned diacyl peroxides, the above-mentioned peroxy esters, and the above-mentioned azo compounds are preferable.

Illustrative example of the photo radical polymerization initiator includes: benzoin ketals such as 2,2-dimethoxy-1,2-diphenylethane-1-one; α-hydroxy ketones such as 1-hydroxycyclohexyl phenyl ketone, 2-hydroxy-2-methyl-1-phenylpropane-1-one, and 1-[4-(2-hydroxyethoxy)phenyl]-2-hydroxy-2-methyl-1-propane-1-one; α-aminoketones such as 2-benzyl-2-dimethylamino-1-(4-morpholinophenyl)-butane-1-one and 1,2-methyl-1-[4-(methylthio)phenyl]-2-morpholinopropane-1-one; oxime esters such as 1-[(4-phenylthio)phenyl]-1,2-octadione-2-(benzoyl)oxime; phosphine oxides such as bis(2,4,6-trimethylbenzoyl) phenyl phosphine oxide, bis(2,6-dimethoxybenzoyl)-2,4,4-trimethylpentyl phosphine oxide, and 2,4,6-trimethylbenzoyl diphenyl phosphine oxide; 2,4,5-triaryl imidazole dimers such as 2-(o-chlorophenyl)-4,5-diphenyl imidazole dimer, 2-(o-chlorophenyl)-4,5-di(methoxyphenyl) imidazole dimer, 2-(o-fluorophenyl)-4,5-diphenyl imidazole dimer, 2-(o-methoxyphenyl)-4,5-diphenyl imidazole dimer, and 2-(p-methoxyphenyl)-4,5-diphenyl imidazole dimer; benzophenone compounds such as benzophenone, N,N′-tetramethyl-4,4′-diaminobenzophenone, N,N′-tetraethyl-4,4′-diaminobenzophenone, and 4-methoxy-4′-dimethylaminobenzophenone; quinone compounds such as 2-ethylanthraquinone, phenanthrene quinone, 2-tert-butyl anthraquinone, octamethyl anthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphtoquinone, and 2,3-dimethylanthraquinone; benzoin ethers such as benzoin methyl ether, benzoin ethyl ether, and benzoin phenyl ether; benzoin compounds such as benzoin, methyl benzoin, and ethyl benzoin; benzyl compounds such as benzyl dimethyl ketal; acridine compounds such as 9-phenylacridine and 1,7-bis(9,9′-acridinylheptane); and N-phenyl glycine and coumarin.

In the above-mentioned 2,4,5-triaryl imidazole dimer, the aryl substituent groups in two triaryl imidazole moieties may be the same to give a symmetrical compound or different to give an asymmetric compound. In addition, like a combination of diethyl thioxanthone with dimethylamino benzoic acid, a thioxanthone compound may be combined with a tertiary amine.

Among them, in view of curing properties, transparency, and heat resistance, the above-mentioned α-hydroxy ketones and the above-mentioned phosphine oxides are preferable. These thermal and photo radical polymerization initiators may be used singly or in a combination of two or more of them. Besides, they may be used in a combination with a suitable photosensitizer.

In the case that an epoxy resin is used as the polymerizable compound of the (B) component, a thermal cationic polymerization initiator and a photo cationic polymerization initiator may be mentioned as the polymerization initiator of the (B) component; however, a photo cationic polymerization initiator is preferable because the curing rate thereof is fast, and curing can be done at a normal temperature.

Illustrative example of the thermal cationic polymerization initiator includes: benzylsulfonium salts such as a p-alkoxyphenyl benzyl methyl sulfonium hexafluoroantimonate; pyridinium salts such as benzyl-p-cyanopyridinium hexafluoroantimonate, 1-naphthyl-o-cyanopyridinium hexafluoroantimonate, and cinnamyl-o-cyanopyridinium hexafluoroantimonate; and benzyl ammonium salts such as benzyl dimethyl phenyl ammonium hexafluoroantimonate.

Among them, in view of curing properties, transparency, and heat resistance, the above mentioned benzylsulfonium salts are preferable.

Illustrative example of the photo cationic polymerization initiator includes: aryl diazonium salts such as p-methoxybenzene diazonium hexafluorophosphate; diaryl iodonium salts such as diphenyl iodonium hexafluorophosphate and diphenyl iodonium hexafluoroantimonate; triarylsulfonium salts such as triphenylsulfonium hexafluorophosphate, triphenylsulfonium hexafluoroantimonate, diphenyl-4-thiophenoxyphenylsulfonium hexafluorophosphate, diphenyl-4-thiophenoxyphenylsulfonium hexafluoroantimonate, and diphenyl-4-thiophenoxyphenylsulfonium pentafluorohydroxy antimonate; triaryl selenium salts such as triphenyl selenium hexafluorophosphate, triphenyl selenium tetrafluoroborate, and triphenyl selenium hexafluoroantimonate; dialkyl phenacyl sulfonium salts such as dimethyl phenacyl sulfonium hexafluoroantimonate and diethyl phenacyl sulfonium hexafluoroantimonate; dialkyl-4-hydroxide salts such as 4-hydroxyphenyl dimethyl sulfonium hexafluoroantimonate and 4-hydroxyphenyl benzyl methyl sulfonium hexafluoroantimonate; and sulfonate esters such as orhydroxymethyl benzoin sulfonate ester, N-hydroxyimide sulfonate, orsulfonyloxy ketone, and β-sulfonyloxy ketone.

Among them, in view of curing properties, transparency, and heat resistance, the abovementioned triarylsulfonium salts are preferable. These thermal and photo cationic polymerization initiators may be used singly or in a combination of two or more of them. Besides, they may be used in a combination with a suitable photosensitizer.

Blending amount of the polymerization initiator of the (C) component is preferably in the range of 0.1 or more parts by mass to 10 or less parts by mass relative to 100 parts by mass as the total mass of the (A) component and the (B) component. If the amount is less than 0.1 parts by mass, curing is sometimes insufficient, while if the amount is more than 10 parts by mass, light transmittance is sometimes insufficient. In view of the above-mentioned, the amount thereof is more preferably in the range of 0.3 or more parts by mass to 7 or less parts by mass, while especially preferably in the range of 0.5 or more parts by mass to 5 or less parts by mass.

In addition, besides them, if the need arises, the photosensitive resin composition for forming a member having a curved shape of the present invention may be added with so-called additives such as an antioxidant, an anti-yellowing agent, a UV absorber, a visible light absorber, a coloring material, a plasticizer, a stabilizer, and a filler with the amount thereof not causing an adverse effect to the present invention.

### Photosensitive Resin Composition for Forming a Member Having a Curved Shape:

The photosensitive resin composition for forming a member having a curved shape of the present invention may be diluted by a suitable organic solvent so that it may be used as a photosensitive resin varnish for forming a member having a curved shape. As to the organic solvent to be used, there is no particular restriction in it, provided that it can dissolve the resin composition; and therefore, illustrative example thereof includes: aromatic hydrocarbons such as toluene, xylene, mesitylene, cumene, and p-cymene; cyclic ethers such as tetrahydrofuran and 1,4-dioxane; alcohols such as methanol, ethanol, isopropanol, butanol, ethylene glycol, and propylene glycol; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, and γ-butyrolactone; carbonate esters such as ethylene carbonate and propylene carbonate; polyvalent alcohol alkyl ethers such as ethylene glycol monomethyl ether, ethylene glycol monoethyl ether, ethylene glycol monobutyl ether, ethylene glycol dimethyl ether, ethylene glycol diethyl ether, propylene glycol monomethyl ether, propylene glycol monoethyl ether, propylene glycol dimethyl ether, propylene glycol diethyl ether, diethylene glycol monomethyl ether, diethylene glycol monoethyl ether, diethylene glycol monobutyl ether, diethylene glycol dimethyl ether, and diethylene glycol diethyl ether; polyvalent alcohol alkyl ether acetates such as ethylene glycol monomethyl ether acetate, ethylene glycol monoethyl ether acetate, ethylene glycol monobutyl ether acetate, propylene glycol monomethyl ether acetate, propylene glycol monoethyl ether acetate, diethylene glycol monomethyl ether acetate, and diethylene glycol monoethyl ether acetate; and amides such as N,N-dimethylformamide, N,N-diemthylacetamide, and N-methyl pyrrolidone.

Among them, in view of solubility and boiling point, toluene, methanol, ethanol, isopropanol, acetone, methyl ethyl ketone, methyl isobutyl ketone, cyclohexanone, methyl acetate, ethyl acetate, butyl acetate, methyl lactate, ethyl lactate, ethylene glycol monomethyl ether, ethylene glycol monoethyl ether, propylene glycol monomethyl ether, propylene glycol monoethyl ether, diethylene glycol dimethyl ether, ethylene glycol monomethyl ether acetate, propylene glycol monomethyl ether acetate, and N,N-dimethylacetamide are preferable.

These organic solvents may be used singly or in a combination of two or more of them. Usually, concentration of the solid component in the resin varnish is preferably in the range of 20% or more by mass to 80% or less by mass.

Preparation of the photosensitive resin varnish for forming a member having a curved shape is done preferably by mixing with stirring. Although the stirring method thereof is not particularly restricted, in view of stirring efficiency, stirring with a stirrer having a propeller is preferable. Although the rotation speed of the stirrer's propeller is not particularly restricted, it is preferably in the range of 10 rpm or more to 1,000 rpm or less. If the rotation speed thereof is less than 10 rpm, sometimes there is a case that each component of the (A) to (C) components and the organic solvent are not mixed well, while if the rotation speed thereof is more than 1,000 rpm, significant incorporation of air bubbles due to rotation of the propeller takes place. In view of the above-mentioned, the rotation speed thereof is more preferably in the range of 50 rpm or more to 800 rpm or less, while especially preferably in the range of 100 rpm or more to 500 rpm or less. Although the stirring time is not particularly restricted, the stirring time is preferably in the range of 1 hour or longer to 24 hours or shorter. If the stirring time is shorter than 1 hour, sometimes there is a case that each component of the (A) to (C) components and the organic solvent are not mixed well, while if the stirring time is longer than 24 hours, the time for preparation of the varnish cannot be made shorter.

The thus prepared photosensitive resin varnish for forming a member having a curved shape is preferably filtrated by using a filter having pore diameter of 50 μm or less. If the pore diameter thereof is larger than 50 μm, coarse foreign matters and so forth cannot be removed thereby sometimes leading to formation of particles and the like during coating of the varnish; and in addition, scattering of the light which propagates the lens member cannot be suppressed. In view of the above-mentioned, it is more preferable to filter the varnish by using a filter having pore diameter of 30 μm or less, while especially preferably the filtration is made by using a filter having pore diameter of 10 μm or less.

It is preferable that the prepared photosensitive resin varnish for forming a member having a curved shape be defoamed under reduced pressure. Although there is no particular restriction in the defoaming method, specifically, a vacuum pump and a bell jar as well as a defoaming equipment attached with a vacuum machine may be used. Although the pressure during evacuation is not particularly restricted, the pressure at which an organic solvent contained in the resin varnish may not boil is preferable. Although the defoaming time under reduced pressure is not particularly restricted, the defoaming time is preferably in the range of 3 minutes or longer to 60 minutes or shorter. If the defoaming time is shorter than 3 minutes, the air bubbles dissolved in the resin varnish cannot be removed. On the other hand, if the defoaming time is longer than 60 minutes, the organic solvent contained in the resin varnish evaporates.

The refractive index of the cured film obtained by curing due to polymerization of the photosensitive resin composition for forming a member having a curved shape of the present invention which comprises the (A) polymer, the (B) polymerizable compound having a thermally reactive group, and the (C) polymerization initiator is preferably in the range of 1.400 or more to 1.700 or less at the temperature of 25° C. and the wave length in the range of 830 nm or more to 850 nm or less. If the refractive index is in the range of 1.400 or more to 1.700 or less, this refractive index is not significantly different from those of usual optical resins, so that general versatility as the optical material is not damaged. In view of the above-mentioned, the refractive index is more preferably in the range of 1.425 or more to 1.675 or less, while especially preferably in the range of 1.450 or more to 1.650 or less.

The transmittance of the cured film having the thickness of 50 μm obtained by curing due to polymerization of the photosensitive resin composition for forming a member having a curved shape of the present invention which comprises the (A) polymer, the (B) polymerizable compound having a thermally reactive group, and the (C) polymerization initiator, is preferably 80% or more at the wave length of 400 nm. If the transmittance is less than 80%, amount of the transmitted light is insufficient. In view of the above-mentioned, the transmittance is more preferably 85% or more. Meanwhile, upper limit of the transmittance is not particularly restricted.

### Photosensitive Resin Film for Forming a Member Having a Curved Shape:

The photosensitive resin film for forming a member having a curved shape of the present invention which comprises the above-mentioned photosensitive resin composition for forming a member having a curved shape can be readily produced by applying the photosensitive resin varnish for forming a member having a curved shape comprising the (A) to (C) components onto a suitable base film, which is followed by removing the solvent contained therein. Alternatively, the resin film may be produced by directly applying the photosensitive resin composition for forming a member having a curved shape onto the base film.

As to the base film, there is no particular restriction in it; and therefore, illustrative example thereof includes: polyesters such as polyethylene terephthalate, polybutylene terephthalate, and polyethylene naphthalate; polyolefins such as polyethylene and polypropylene; and polycarbonate, polyamide, polyimide, polyamide imide, polyether imide, polyether sulfide, polyether sulfone, polyether ketone, polyphenylene ether, polyphenylene sulfide, polyarylate, polysulfone, and liquid crystal polymers. Among them, in view of flexibility and toughness, polyethylene terephthalate, polybutylene terephthalate, polyethylene naphthalate, polypropylene, polycarbonate, polyamide, polyimide, polyamide imide, polyphenylene ether, polyphenylene sulfide, polyarylate, and polysulfone are preferable.

Although thickness of the base film may be arbitrarily changed in accordance with the intended flexibility, the thickness thereof is preferably in the range of 3 μm or more to 250 μm or less. If the thickness is less than 3 μm, the film strength thereof is insufficient, while if the thickness is more than 250 μm, sufficient flexibility cannot be obtained. In view of the above-mentioned, the film thickness is more preferably in the range of 5 μm or more to 200 μm or less, while especially preferably in the range of 7 μm or more to 150 μm or less.

Meanwhile, in order to improve the exfoliating property from the resin layer, the film treated with a releasing treatment by a silicone compound, a fluorine-containing compound, or the like may be used, if the need arises.

The photosensitive resin film for forming a member having a curved shape that is obtained by applying the photosensitive resin varnish for forming a member having a curved shape or the photosensitive resin composition for forming a member having a curved shape may be adhered, if the need arises, with a protective film on the resin layer thereby forming a three layer structure comprising the base film, the resin layer, and the protective film.

As to the protective film, there is no particular restriction in it; and therefore, illustrative example thereof includes: polyesters such as polyethylene terephthalate, polybutylene terephthalate, and polyethylene naphthalate; and polyolefins such as polyethylene and polypropylene. Among them, in view of flexibility and toughness, polyesters such as polyethylene terephthalate and polyolefins such as polyethylene and polypropylene are preferable. Meanwhile, in order to improve the exfoliating property from the resin layer, the film treated with a releasing treatment by a silicone compound, a fluorine-containing compound, or the like may be used, if the need arises.

Although thickness of the protective film may be arbitrarily changed in accordance with the intended flexibility, the thickness thereof is preferably in the range of 10 μm or more to 250 μm or less. If the thickness is less than 10 μm, film strength thereof is insufficient, while if the thickness is more than 250 μm, sufficient flexibility cannot be obtained. In view of the above-mentioned, film thickness thereof is more preferably in the range of 15 μm or more to 200 μm or less, while especially preferably in the range of 20 μm or more to 150 μm or less.

As to the thickness of the resin layer of the photosensitive resin film for forming a member having a curved shape of the present invention, although there is no particular restriction in it, usually the thickness thereof after drying is preferably in the range of 5 μm or more to 500 μm or less. If the thickness thereof is less than 5 μm, because the thickness is insufficient, strength of the resin film or a cured product of the resin film is insufficient, while if the thickness is more than 500 μm, because drying thereof cannot be done well, amount of the solvent remained in the resin film increases thereby sometimes causing foaming when the cured product of the said film is heated. When thickness of the photosensitive layer is made within the above-mentioned range, performance as the lens member after exposure and development can be secured more surely. Adjustment of the thickness of the coat film can be made by changing, for example, amount of the coating solution and amount of the solvent contained therein.

The photosensitive resin film for forming a member having a curved shape thereby obtained may be easily stored, for example, by rolling it up into a rolled state. Alternatively, it may be stored in the state of a sheet by cutting the film, which is in a rolled state, into a suitable size.

The photosensitive resin composition for forming a member having a curved shape of the present invention is suitable as a photosensitive resin composition for forming a member having a curved shape; and likewise, the photosensitive resin film for forming a member having a curved shape of the present invention is suitable as a photosensitive resin film for forming a member having a curved shape.

### Method for Forming a Member Having a Curved Shape:

Hereunder, the method for producing a member having a curved shape (lens member) of the present invention will be explained.

The method for producing a lens member of the present invention is not particularly restricted, while illustrative example thereof includes a production method by using the photosensitive resin varnish for forming a member having a curved shape by a spin coating method or the like, and a production method by using the photosensitive resin film for forming a member having a curved shape by a laminating method. And also, the method in which these methods are combined may be used for the production thereof. Among them, in order that the production process for a lens member with excellent productivity can be provided, the production method by using the photosensitive resin film for forming a member having a curved shape by a laminating method is preferable.

### Pre-Treatment Process: Preparation of a Photosensitive Resin Layer for Forming a Member Having a Curved Shape

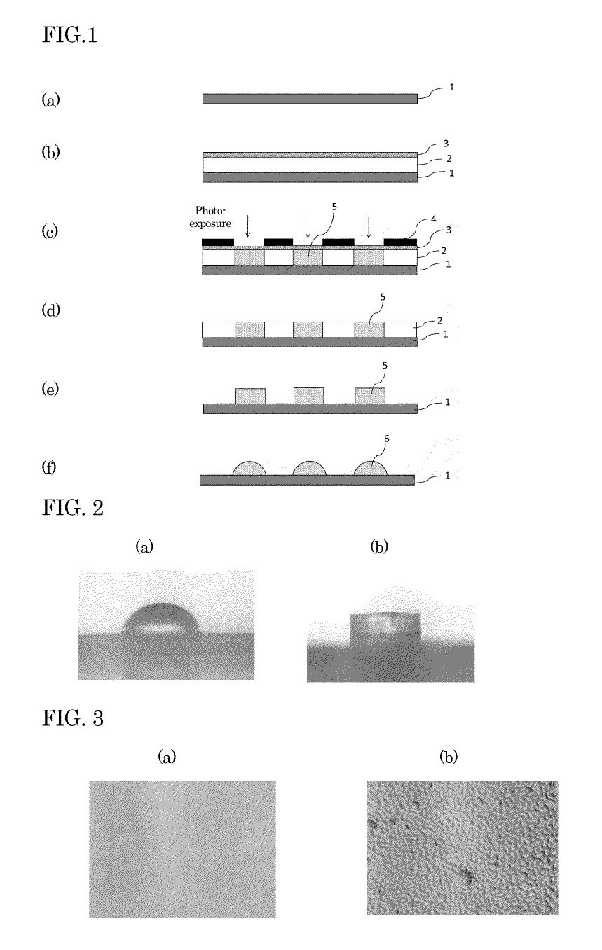

Firstly, as shown in FIGS. 1(a) and 1(b), as the pre-treatment process, the photosensitive resin film for forming a member having a curved shape which has the base film 3 is laminated on the substrate 1 to form the photosensitive resin layer 2 for forming a member having a curved shape.

The photosensitive resin film for forming a member having a curved shape is laminated by pressure bonding so as to contact with the substrate 1. As to the lamination method, a method in which lamination is carried out by pressure bonding with heating by using a roll laminator or a flat plate type laminator may be mentioned; however, in view of adhesion and following property, it is preferable to laminate the resin film for forming a lower clad layer by using a flat plate type laminator under reduced pressure.

Meanwhile, the flat plate type laminator in the present invention means the laminator to carry out pressure bonding by pressing a pair of flat plates between which materials to be laminated are sandwiched; and for example, a vacuum pressing type laminator may be suitably used. The heating temperature at this time is preferably in the range of 40° C. or higher to 130° C. or lower, and the pressure for pressure bonding is preferably in the range of 0.1 MPa or more to 1.0 MPa or less, though the conditions are not particularly restricted. If a protective film is present in the resin film for forming a lower clad layer, the lamination is carried out after the protective film is removed.

Meanwhile, before lamination by the vacuum pressing type laminator, the photosensitive resin film for forming a member having a curved shape may be temporarily adhered onto the substrate 1 by using a roll laminator in advance. At this time, in order to improve adhesion and following property, preferably this temporary adhesion is carried out with pressure bonding; and at this time, the pressure bonding may be carried out with heating by using a laminator having a heat roll. The temperature for lamination is preferably in the range of 20° C. or higher to 130° C. or lower. If the temperature is lower than 20° C., adhesion between the substrate 1 and the photosensitive resin layer 2 for forming a member having a curved shape becomes poor, while if the temperature is higher than 130° C., the resin layer flows too much at the time of roll lamination so that a necessary film thickness cannot be obtained. In view of the above-mentioned, the temperature is more preferably in the range of 40° C. or higher to 100° C. or lower. The pressure is preferably in the range of 0.2 MPa or more to 0.9 MPa or less, and the laminating rate is preferably in the range of 0.1 m/minute or more to 3 m/minute or less, though these conditions are not particularly restricted.

As to the substrate 1, there is no particular restriction in it and therefore, illustrative example thereof includes a glass epoxy resin substrate, a ceramic substrate, a glass substrate, a silicon substrate, a plastic substrate, a metal substrate, a resin-layer attached substrate, a metal-layer attached substrate, a plastic film, a resin-layer attached plastic film, a metal-layer attached plastic film, and an electric wiring board, wherein especially a substrate having a light shielding effect to an active beam with which the resin for forming a member having a columnar shape and the resin for forming a lens member are photo-cured (these will be discussed later) is preferable.

For example, if the active beam with which the resin for forming a member having a columnar shape is photo-cured is a UV beam, substrates such as a metal substrate, and a plastic substrate and a glass epoxy resin substrate which do not transmit a UV beam are preferable.

Thickness of the substrate is not particularly restricted; however, in order to secure the strength and to reduce a light loss due to shortening of the light pass, the thickness thereof is preferably in the range of 5 μm or more to 1 mm or less, while more preferably in the range of 10 μm or more to 100 μm or less.

### Step 1: Photo-Curing and Patterning Process

As shown in FIG. 1(c), in Step 1, the columnar part 5 is formed by exposing the photosensitive layer by using the photomask 4. Specifically, an active beam is irradiated through the photomask having a negative or a positive mask pattern, which is called as an art work, so as to make an image pattern. Alternatively, the active beam may be radiated directly to an image pattern, without going through the photomask, by using a laser direct drawing method. Illustrative example of the light source of the active beam includes heretofore known light sources which can effectively radiate a UV beam, such as a carbon arc lamp, a mercury vapor arc lamp, a super high pressure mercury lamp, a high pressure mercury lamp, and a xenon lamp. In addition, light sources which can effectively radiate a visible light, such as a flood bulb for pictures and a solar lamp may be mentioned.

Here, the radiation amount of the active beam is preferably in the range of 0.01 J/cm² or more to 10 J/cm² or less. If the radiation amount is less than 0.01 J/cm², the curing reaction does not take place sufficiently well thereby sometimes leading to outflow of the lens pattern (columnar part) in the development process, while if the radiation amount is more than 10 J/cm², to realize the curved shape by heat sagging during a heat treatment becomes difficult because of excess radiation amount. In view of the above-mentioned, the radiation amount is more preferably in the range of 0.05 J/cm² or more to 5 J/cm² or less, while especially preferably in the range of 0.1 J/cm² or more to 3 J/cm² or less.

Meanwhile, after the photo-exposure, in order to improve resolution power and adhesion of the columnar part 5, a post-exposure heating may be carried out. The time from exposure to the UV beam to the post-exposure heating is preferably within 10 minutes. If the time is within 10 minutes, the active species which are generated by exposure to the UV beam may not be inactivated. The temperature of the post-exposure heating is preferably in the range of 40° C. or higher to 160° C. or lower; and the time thereof is preferably in the range of 30 seconds or longer to 10 minutes or shorter.

### Step 2: Development Process

In Step 2, after the photo-exposure, as shown in FIG. 1(d), the base film 3 of the photosensitive resin film 2 for forming a member having a curved shape is removed to carry out the development by a heretofore known method such as a spraying method, a swing dipping method, a brushing method, a scrapping method, a dipping method, and a paddle method by using a developing solution such as an alkaline aqueous solution and an aqueous developing solution. In addition, if the need arises, two or more of the development methods may be used concurrently.

As to the base used in the alkaline aqueous solution, there is no particularly restriction in it; and therefore, illustrative example thereof includes: alkaline hydroxides such as hydroxides of lithium, sodium, and potassium; alkaline carbonates of carbonate salts or bicarbonate salts of lithium, sodium, potassium, and ammonium; alkaline metal phosphate salts such as potassium phosphate and sodium phosphate; alkaline metal pyrophosphate salts such as sodium pyrophosphate and potassium pyrophosphate; sodium salts such as borax and sodium metasilicate; and organic bases such as tetramethyl ammonium hydroxide, triethanolamine, ethylene diamine, diethylene triamine, 2-amino-2-hydroxymethyl-1,3-propane diol, and 1,3-diaminopropanol-2-morpholine. The pH of the alkaline aqueous solution to be used for developing is preferably in the range of 9 or more to 11 or less; and the temperature thereof is adjusted in accordance with the development properties of the resin composition for forming the core part. In addition, the alkaline aqueous solution may be mixed with a surfactant, a defoaming agent, a small amount of an organic solvent to facilitate the development, or the like.

As to the aqueous developing solution, there is no particular restriction in it, provided that the said solution comprises water or an alkaline aqueous solution and one or more of the organic solvents. The pH of the aqueous developing solution is preferably as narrow as possible within the range in which development of the resin film for forming the core part can be done sufficiently well; and therefore, the pH thereof is preferably in the range of 8 or more to 12 or less, while especially preferably in the range of 9 or more to 10 or less.

Illustrative example of the organic solvent includes: alcohols such as methanol, ethanol, isopropanol, butanol, ethylene glycol, and propylene glycol; ketones such as acetone and 4-hydroxy-4-methyl-2-pentanone; polyvalent alcohol alkyl ethers such as ethylene glycol monomethyl ether, ethylene glycol monoethyl ether, propylene glycol monomethyl ether, propylene glycol monoethyl ether, diethylene glycol monomethyl ether, diethylene glycol monoethyl ether, and diethylene glycol monobutyl ether.

These may be used singly or in a combination of two or more of them. Usually, concentration of the organic solvent therein is preferably in the range of 2% or more by mass to 90% or less by mass, and temperature thereof is adjusted in accordance with the development properties of the resin composition for forming the core part. In addition, the aqueous developing solution may be mixed with a small amount of a surfactant, a defoaming agent, or the like.

As the post-development treatment, if the need arises, the columnar part 5 of the optical waveguide may be cleaned by using a cleaning solution comprising water and the above-mentioned organic solvent. The organic solvent may be used singly or in a combination of two or more of them. Usually, concentration of the organic solvent therein is preferably in the range of 2% or more by mass to 90% or less by mass, and the temperature thereof is adjusted in accordance with the development properties of the resin composition for forming the core part.

As the post-development treatment or the post-cleaning treatment, if the need arises, the columnar part 5 may be further cured by heating in the temperature range of about 60° C. or higher to 250° C. or lower, or by photo-exposure with the radiation amount in the range of 0.1 mJ/cm² or more to 1000 mJ/cm² or less.

### Step 3: Heat Treatment (Heat Sagging) Process

Next, in Step 3, the columnar part 5 formed on the substrate 1 is heated to carry out the heat sagging process and the heat curing process at the same time, so that the lens member 6 having excellent heat resistance can be obtained. As to the heating method, heretofore known methods such as a hot air radiation method and a heating method by infrared beam radiation may be mentioned; however, there is no particular restriction, provided that the lens pattern formed on the substrate can be effectively heated by the said method.

Temperature at the time of heating is preferably in the range of 60° C. or higher to 200° C. or lower, more preferably in the range of 80° C. or higher to 180° C. or lower, while especially preferably in the range of 100° C. or higher to 160° C. or lower. If this heating temperature is lower than 60° C., the heat sagging effect is prone to be insufficient, while if the temperature is higher than 200° C., components to constitute the photosensitive resin composition layer is prone to thermally decompose.

### EXAMPLES

Hereunder, Examples of the present invention will be explained more specifically.

### Example 1

### Base Polymer

### Preparation of (Meth)Acryl Polymer (P-1)

Into a flask equipped with a stirrer, a cooling tube, a gas introducing tube, a dropping funnel, and a thermometer were weighed 42 parts by mass of propylene glycol monomethyl ether acetate and 21 parts by mass of methyl lactate; and then, the resulting mixture was stirred with introducing a nitrogen gas. After the liquid temperature thereof was raised to 65° C., into this mixture was gradually added during a period of 3 hours a mixture of 14.5 parts by mass of N-cyclohexyl maleimide, 20 parts by mass of benzyl acrylate, 39 parts by mass of o-phenyl phenol 1.5 EO acrylate, 14 parts by mass of 2-hydroxyethyl methacrylate, 12.5 parts by mass of methacrylic acid, 4 parts by mass of 2,2′-azobis(2,4-dimethylvaleronitrile), 37 parts by mass of propylene glycol monomethyl ether acetate, and 21 parts by mass of methyl lactate; and then, this reaction mixture was stirred at 65° C. for 3 hours, and then, at 95° C. for 1 hour to obtain the solution of the (meth)acryl polymer (P-1) (solid component of 45% by mass).

### Measurement of Acid Value:

The acid value of P-1 was determined to be 79 mg-KOH/g as a result of the measurement thereof. Meanwhile, the acid value was calculated from the amount of the 0.1 mol/L potassium hydroxide aqueous solution necessary to neutralize the P-1 solution. In this measurement, the point at which the color of the colorless phenolphthalein added as an indicator changed to a pink color was taken as the neutral point thereof

### Measurement of Weight-Average Molecular Weight:

As a result of measurement by using a GPC (“SD-8022”, “DP-8020”, and “RI-8020”; all manufactured by Tosoh Corp.), the weight-average molecular weight of P-1 was determined to be 2.5×10⁴. Meanwhile, the columns “Gelpack GL-A150-S” and “Gelpack GL-A160-S” (both manufactured by Hitachi Chemical Co., Ltd.) were used here. In the measurement, the eluting solution of tetrahydrofuran was used with the sample concentration of 0.5 mg/mL and the eluting rate of 1 mL/minute.

### Preparation of the Photosensitive Resin Varnish (LEV-1) for Forming a Member Having a Curved Shape:

Into a plastic bottle having a wide opening were weighed 60 parts by mass of P-2 solution (solid component of 45% by mass) as the (A) alkaline-soluble (meth)acryl polymer, 40 parts by mass of bisphenol A type epoxy acrylate (“EA-1010N” with epoxy equivalent of 518 g/eq; manufactured by Shin-Nakamura Chemical Co., Ltd.) as the (B) polymerizable compound,

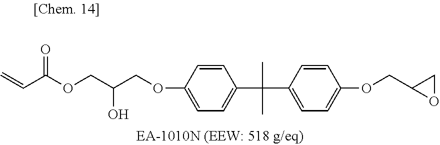 [SMILES: C=CC(=O)OCC(O)COc1ccc(C(C)(C)c2ccc(OCC3CO3)cc2)cc1]

1 part by mass of 1-[4-(2-hydroxyethoxy)phenyl]-2-hydroxy-2-methyl-1-proane-1-one (“Irgacure 2959”; manufactured by BASF Japan Ltd.) as the (C) polymerizable initiators, and 1 part by mass of bis(2,4,6-trimethylbenzoyl)phenyl phosphine oxide (“Irgacure 819”; manufactured by BASF Japan Ltd.); and then, the resulting mixture was stirred at the rotation speed of 400 rpm and at 25° C. for 6 hours to obtain the resin varnish for forming the core part. Then, this mixture was filtrated under the conditions of the temperature of 25° C. and the applied pressure of 0.4 MPa by using a polyflon filter having pore diameter of 2 μm (“PF020”; manufactured by Advantec Toyo Kaisha, Ltd.) and a membrane filter having pore diameter of 0.5 μm (“J050A”; manufactured by Advantec Toyo Kaisha, Ltd.). Thereafter, vacuum defoamation thereof was carried out under the evacuation degree of 50 mmHg for 15 minutes by using a vacuum pump and a bell jar to obtain the photosensitive resin varnish LEV-1 for forming a member having a curved shape.

### Preparation of the Photosensitive Resin Film (LEF-1) for Forming a Member Having a Curved Shape:

After the above-mentioned photosensitive resin varnish (LEV-1) for forming a member having a curved shape was applied onto a untreated surface of a PET film (“A1517” with the film thickness of 16 μm; manufactured by Toyobo Co., Ltd.) by using a coating machine (“Multicoater TM-MC”; manufactured by Hirano Tecseed Co., Ltd.), it was dried at 100° C. for 20 minutes; and then, as the protective film, a releasing PET film (“A31” with the film thickness of 25 μm; manufactured by Teijin DuPont films Japan Ltd.) was adhered with it to obtain the photosensitive resin film (LEF-1) for forming a member having a curved shape. At this time, the film thickness of the resin layer can be arbitrarily adjusted by controlling a gap of the coating machine; and in this Example, the adjustment thereof was made such that the film thickness after curing might become 50 μm.

### Examples 2 and 3 and Comparative Examples 1 to 3

The same procedure as that of Example 1 was repeated to prepare each of the photosensitive resin films (LEF-2 to 6) for forming a member having a curved shape by mixing each of the photosensitive resin varnish (LEV-2 to 6) for forming a member having a curved shape in accordance with the blending ratios shown in Table 1.

### Measurement of Light Transmittance at the Wavelength of 850 nm:

The photosensitive resin film for forming a member having a curved shape obtained after removal of the protective film (Purex A31) was laminated on a slide glass (size of 76 mm×26 mm, with the thickness of 1 mm) by using the before-mentioned vacuum laminator under the conditions of the pressure of 0.4 MPa, the temperature of 50° C., and the pressing time of 30 seconds. Next, by using a UV beam radiating machine, a UV beam (wavelength of 365 nm) was radiated with the radiation amount of 1000 mJ/cm²; and then, it was heated at 160° C. for 1 hour to obtain a sample for measurement of the light transmittance. The transmittance of this sample at the wavelength of 850 nm was measured by using a spectrophotometer (“U-3310”; manufactured by Hitachi High-Technologies Corp.).

### Measurement of Refractive Index:

Similarly to the sample for measurement of the light transmittance, the photosensitive resin film for forming a member having a curved shape was laminated onto a silicon substrate (size of 60×20 mm with the thickness of 0.6 mm); and then, it was cured to obtain the sample for measurement of the refractive index. The refractive index of this sample at the wavelength of 830 nm was measured by using a prism coupling type refractive index measurement instrument (“Model 12020”; manufactured by Metricon Corp.).

### Method for Making the Lens Member:

The photosensitive resin film (LEF-1) for forming a member having a curved shape obtained after removal of the protective film (Purex A31) was laminated on a glass epoxy resin substrate (“MCL-E-679FB” with the thickness of 0.6 mm, wherein a copper foil was removed by etching; manufactured by Hitachi Chemical Co., Ltd.) by using a vacuum pressing type laminator (“MVLP-500/600”; manufactured by Meiki Co., Ltd.) under the conditions of the pressure of 0.4 MPa, the temperature of 80° C., and the pressing time of 30 seconds. Next, via the negative photomask 4 having a lens pattern, the photosensitive resin film for forming a member having a curved shape (lens pattern 4) was exposed to a UV beam (wavelength of 365 nm) by using a UV beam radiating machine with the radiation amount of 2500 mJ/cm². And then, after the supporting film (“Cosmoshine A1517”; manufactured by Toyobo Co., Ltd.) was removed, development was carried out with an aqueous solution of 1% by mass of sodium carbonate under the conditions of the temperature of 30° C., the spray pressure of 0.15 MPa, and the developing time of 105 seconds by using a spray type developing machine (“RX-40D”; manufactured by Yamagata Machinery Co., Ltd.) to obtain the columnar part 5. Subsequently, it was cleaned by pure water; and then, the curing and heat sagging thereof was carried out at 160° C. for 1 hour.

### Evaluation of Cross Section of the Lens Member:

The lens member was cut in the direction perpendicular to the substrate direction by using a dicing saw (“DAD-341”; manufactured by DISCO Corp.); and by observing the cross section, the evaluation was made as to whether or not the curved shape was obtained.

Good: the columnar part has a curved shape.

Bad: the columnar part has a rectangular shape.

### Evaluation of Heat Resistance:

In the lens member obtained by using the photosensitive resin composition for forming a member having a curved shape of the present invention, in order to confirm the change of the shape of the lens due to its thermal history such as reflow, the photosensitive resin composition for forming a member having a curved shape was evaluated in the way as shown below.

### Heat Resistance Evaluation (1): Shape of the Resin Surface

### Preparation Method of the Sample:

Similarly to the sample for measurement of the light transmittance, the photosensitive resin film for forming a member having a curved shape was laminated onto a silicon substrate (size of 60×20 mm with the thickness of 0.6 mm); and then, by using a UV beam radiating machine, a UV beam (wavelength of 365 nm) was radiated with the radiation amount of 2500 mJ/cm²; and then, it was heated at 160° C. for 1 hour. Further, in order to facilitate observation of the surface state after the thermal history, Au with the thickness of 0.5 μm was vapor-deposited by using a vapor depositing machine (“RE-0025”; manufactured by First Giken Co., Ltd.).

### Evaluation Method:

The sample thus obtained was heated at 1 hour for 200° C.; and then, the shape after the thermal history was observed.

Good: the deposited surface of Au is smooth.

Bad: wrinkles and projections are formed on the deposited surface of Au.

### Heat Resistance Evaluation (2): Light Loss:

### Preparation Method of the Sample:

In the polyimide film substrate (“Upilex RN” with the thickness of 25 μm; manufactured by Ube-Nitto Kasei Co., Ltd.) with the size of 150 mm×150 mm, a through hole with the diameter of 210 μm is formed by a drill processing method to obtain the substrate having a through hole. Next, the photosensitive resin film for forming a member having a curved shape having the thickness of 50 μm obtained after removal of the cover film was evacuated to 500 Pa or less by using a vacuum pressing type laminator (“MVLP-500”; manufactured by Meiki Co., Ltd.); and then, it was laminated by a thermal press adhesion method onto the substrate obtained as mentioned above under the conditions of the pressure of 0.4 MPa, the temperature of 110° C., and the pressing time of 30 seconds, thereby filling up inside the through hole with the photosensitive resin composition for forming a member having a curved shape and at the same time forming on the said substrate the photosensitive resin layer for forming a member having a curved shape.

Next, the photosensitive resin film for forming a member having a curved shape (lens pattern 4) was radiated with a UV beam (wavelength of 365 nm) from the through hole opening with the radiation amount of 2500 J/cm² by using a UV beam radiating machine. And then, after the supporting film (“Cosmoshine A1517”; manufactured by Toyobo Co., Ltd.) was removed, development was carried out with an aqueous solution of 1% by mass of sodium carbonate under the conditions of the temperature of 30° C., the spray pressure of 0.15 MPa, and the developing time of 105 seconds by using a spray type developing machine (“RX-40D”; manufactured by Yamagata Machinery Co., Ltd.) to obtain the columnar part. Subsequently, it was cleaned by pure water; and then, the curing and heat sagging thereof was carried out at 160° C. for 1 hour to obtain the lens member on the substrate having the through hole.

### Evaluation Method:

By using a photo fiber for the GI 50 multimode, a photo signal of 850 nm was entered from the through hole in the lower surface of the obtained substrate, thereby it was propagated and concentrated into the lens member; and then, the signal was received by a photo fiber for the GI 62.5 multimode arranged on the extended line vertical to the lens member to measure the light loss. The distance of 100 μm from the photo fiber end to the lens member was used. The value at this time was taken as the light loss (A), and the value measured after the thermal history at 200° C. for 1 hour was taken as the light loss (B).

From the above, the incremental light loss (C) by the thermal history was calculated in accordance with the following equation.

(C)=(B)−(A) Equation:

The evaluation results of Examples 1 to 3 and Comparative Examples 1 to 3 are shown in Table 1; the shapes of the lens members of Example 2 and Comparative Example 2 are shown in FIGS. 2(a) and 2(b); and the appearances of the resin surfaces of Example 2 and Comparative Example 1 after the heat resistance test are shown in FIGS. 3(a) and 3(b).

TABLE

| | | | | | | Comparative | Comparative | Comparative |
|---|---|---|---|---|---|---|---|---|
| | | | Example 1 | Example 2 | Example 3 | Example 1 | Example 2 | Example 3 |
| | | | LEV-1 | LEV-2 | LEV-3 | LEV-4 | LEV-5 | LEV-6 |
| Item | Ingredient (parts by mass) | | (LEF-1) | (LEF-2) | (LEF-3) | (LEF-4) | (LEF-5) | (LEF-6) |
| (A) | Base polymer (P-1)¹⁾ | | 60 (solid | 65 (solid | 70 (solid | 60 (solid | 60 (solid | 60 (solid |
| Component | | | component) | component) | component) | component) | component) | component) |
| (B) | EA-1010N²⁾ | | 40 | 35 | 30 | — | — | — |
| Component | HOA-MPEH³⁾ | | — | — | — | 35 | — | — |
| | FA-324A⁴⁾ | | — | — | — | — | 20 | 15 |
| | FA-321A⁵⁾ | | — | — | — | 5 | 20 | 15 |
| | NC-3000⁶⁾ | | — | — | — | — | | 10 |
| (C) | 2959⁷⁾ | | 1 | 1 | 1 | 1 | 1 | 1 |
| Component | 819⁸⁾ | | 1 | 1 | 1 | 1 | 1 | 1 |
| Evaluation | Refractive index of film | | 1.557 | 1.556 | 1.555 | 1.548 | 1.554 | 1.554 |
| | Transmittance of film (850 nm) | | 99.3 | 99.4 | 99.3 | 99.3 | 99.2 | 99.3 |
| | Lens formability | | Good | Good | Good | Good | Bad | Bad |
| | Heat | Appearance | Good | Good | Good | Bad | Bad | Bad |
| | resistance | of resin | | | | | | |
| | | surface | | | | | | |
| | | Incremental | 0.05 | 0.04 | 0.02 | 0.30 | — | — |
| | | light loss C | | | | | | |
| | | (dB) | | | | | | |

1) The (meth)acryl polymer solution prepared in Example 1 (the weight-average molecular weight of 2.5×10⁴, and the acid value of 80 mg-KOH/g)
2) Bisphenol A type epoxy acrylate (“EA-1010N” with epoxy equivalent of 518 g/eq; manufactured by Shin-Nakamura Chemical Co., Ltd.)
3) Hydroxyethyl acryloyloxyethyl phthalate (“HOA-MPEH” (β-hydroxyethyl-β′-acryloyloxy-o-phthalate); manufactured by Kyoeisya Chemical Co., Ltd.)
4) Ethoxylated bisphenol A diacrylate (“Fancryl FA-324A”; manufactured by Hitachi Chemical Co., Ltd.)

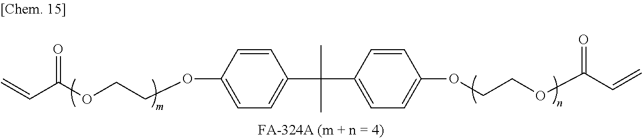

5) Ethoxylated bisphenol A diacrylate (“Fancryl FA-321A”; manufactured by Hitachi Chemical Co., Ltd.)

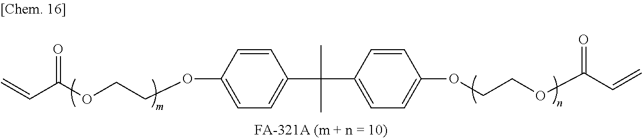

6) Phenol biphenylene type epoxy resin (“NC-3000” with epoxy equivalent of 275 g/eq; manufactured by Nippon Kayaku Co., Ltd.)

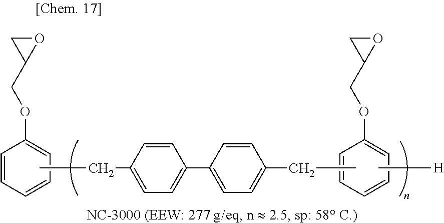

7) 1-[4-(2-Hydroxyethoxy)phenyl]-2-hydroxy-2-methyl-1-propane-1-one (“Irgacure 2959”; manufactured by BASF Japan Ltd.)
8) Bis(2,4,6-trimethylbenzoyl)phenyl phosphine oxide (“Irgacure 819”; manufactured by BASF Japan Ltd.)

As shown in Examples 1 to 3, the photosensitive resin composition for forming a member having a curved shape of the present invention has excellent lens formability and transparency; and also, it is remarkably excellent in heat resistance which has been considered problematic in the existing lens members.

As shown in FIG. 3(a), it can be seen that the film of Example 1 has smooth resin surface even after 1 hour of the thermal history at 200° C. On the contrary, the film of Comparative Example 1 shown in FIG. 3(b) forms wrinkles which appear to be formed by flow of the resin after the heat treatment, so that it was confirmed that this is poor in the heat resistance. As a result, it can be considered that the resin composition crosslinked with a base polymer of the present invention is excellent in heat resistance and in keeping the shape of the lens.

### INDUSTRIAL APPLICABILITY

The photosensitive resin composition for forming a member having a curved shape of the present invention is excellent in lens formability, transparency, and heat resistance; and the lens member obtained by using the said composition is extremely excellent in the light concentration.

### REFERENCE SIGNS LIST

1: Substrate
2: Photosensitive resin film for forming a member having a curved shape
3: Base film
4: Photomask (lens pattern)
5: Columnar part
6: Lens member

1. A photosensitive resin composition for forming a member having a curved shape, comprising (A) a polymer, (B) a polymerizable compound having a group which thermally reacts with the polymer, and (C) a polymerization initiator.

2. The photosensitive resin composition for forming a member having a curved shape according to claim 1, wherein the (A) polymer has a carboxyl group.

3. The photosensitive resin composition for forming a member having a curved shape according to claim 1, wherein the (A) polymer has a weight-average molecular weight of in the range of 1,000 or more to 300,000 or less.

4. The photosensitive resin composition for forming a member having a curved shape according to claim 1, wherein the (A) polymer has a maleimide skeleton in a main chain thereof.

5. The photosensitive resin composition for forming a member having a curved shape according to claim 1, wherein the (B) polymerizable compound comprises a compound having an epoxy group and an ethylenic unsaturated group in its molecule.

6. The photosensitive resin composition for forming a member having a curved shape according to claim 5, wherein the compound having an epoxy group and an ethylenic unsaturated group in its molecule is the one which contains an alicyclic ring or an aromatic ring in its molecule.

7. The photosensitive resin composition for forming a member having a curved shape according to claim 5, wherein the compound having an epoxy group and an ethylenic unsaturated group in its molecule is the one which has one epoxy group and one ethylenic unsaturated group in its molecule.

8. The photosensitive resin composition for forming a member having a curved shape according to claim 5, wherein the compound having an epoxy group and an ethylenic unsaturated group in its molecule is the one which has a bisphenol skeleton in its molecule.

9. The photosensitive resin composition for forming a member having a curved shape according to claim 5, wherein the (B) component comprises, in addition to the compound having an epoxy group and an ethylenic unsaturated group in its molecule, a compound having two or more ethylenic unsaturated groups in its molecule, and further, as other component, a compound having two or more epoxy groups in its molecule.

10. The photosensitive resin composition for forming a member having a curved shape according to claim 1, wherein blending amount of the (A) component is in the range of 10% or more by mass to 85% or less by mass relative to total amount of the (A) component and the (B) component, blending amount of the (B) component is in the range of 15% or more by mass to 90% or less by mass relative to total amount of the (A) component and the (B) component, and blending amount of the (C) component is in the range of 0.1 or more parts by mass to 10 or less parts by mass relative to 100 parts by mass as total mass of the (A) component and the (B) component.

11. The photosensitive resin composition for forming a member having a curved shape according to claim 10, wherein blending amount of the (A) component is in the range of 10% or more by mass to 65% or less by mass relative to total amount of the (A) component and the (B) component, and blending amount of the (B) component is in the range of 35% or more by mass to 90% or less by mass relative to total amount of the (A) component and the (B) component.

12. The photosensitive resin composition for forming a member having a curved shape according to claim 1, wherein the resin composition is used in a production method of a curved shape, and the production method comprises:
Step 1 in which a layer of the photosensitive resin composition for forming a member having a curved shape is formed, and thereby, the photosensitive resin composition for forming a member having a curved shape is photo-cured to form an intended pattern by photo-exposure,
Step 2 in which a uncured part of the photosensitive resin composition for forming a member having a curved shape is removed by development to form a columnar member for forming a member having a curved shape, and
Step 3 in which the columnar member for forming a curved shape is heated to cause thermal sagging to form a curved convex shape.

13. A photosensitive resin film for forming a member having a curved shape, wherein the film comprises a resin layer obtained by using the photosensitive resin composition for forming a member having a curved shape according to claim 1.

14. The photosensitive resin film for forming a member having a curved shape according to claim 13, wherein the resin film has a three-layered structure comprising a base film, a resin layer, and a protective film.

15. A method for producing a member having a curved shape, wherein the method is to form a member having a curved shape by using the photosensitive resin composition for forming a member having a curved shape according to claim 1, and the method comprises:
Step 1 in which a layer of the Photosensitive resin composition for forming a member having a curved shape is formed, and thereby, the photosensitive resin composition for forming a member having a curved shape is photo-cured to form an intended pattern by photo-exposure,
Step 2 in which a uncured part of the photosensitive resin composition for forming a member having a curved shape is removed by development to form a columnar member for forming a member having a curved shape, and
Step 3 in which the columnar member for forming a curved shape is heated to cause thermal sagging to form a curved convex shape.

16. A lens which is obtained by using the photosensitive resin composition for forming a member having a curved shape according to claim 1.

17. A method for producing a member having a curved shape, wherein the method is to form a member having a curved shape by using the photosensitive resin film for forming a member having a curved shape according to claim 13, and the method comprises:
Step 1 in which a layer of the photosensitive resin composition for forming a member having a curved shape is formed, and thereby, the photosensitive resin composition for forming a member having a curved shape is photo-cured to form an intended pattern by photo-exposure,
Step 2 in which a uncured part of the photosensitive resin composition for forming a member having a curved shape is removed by development to form a columnar member for forming a member having a curved shape, and
Step 3 in which the columnar member for forming a curved shape is heated to cause thermal sagging to form a curved convex shape.

18. A method for producing a member having a curved shape, wherein the method is to form a member having a curved shape by using the photosensitive resin film for forming a member having a curved shape according to claim 13, the resin film having a three-layered structure comprising a base film, a resin layer, and a protective film, and the method comprises:
Step 1 in which a layer of the photosensitive resin composition for forming a member having a curved shape is formed, and thereby, the photosensitive resin composition for forming a member having a curved shape is photo-cured to form an intended pattern by photo-exposure,
Step 2 in which a uncured part of the photosensitive resin composition for forming a member having a curved shape is removed by development to form a columnar member for forming a member having a curved shape, and
Step 3 in which the columnar member for forming a curved shape is heated to cause thermal sagging to form a curved convex shape.

19. A lens which is obtained by using the photosensitive resin film for forming a member having a curved shape according to claim 13.

20. A lens which is obtained by using the photosensitive resin film for forming a member having a curved shape according to claim 14.

21. A lens which is obtained by using the producing method according to claim 15.
